(19) United States
(12) Patent Application Publication
(10) Pub. No.: US 2018/0061578 A1
(43) Pub. Date: Mar. 1, 2018

(54) STACKED PASSIVE COMPONENT STRUCTURES

(71) Applicant: Apple Inc., Cupertino, CA (US)

(72) Inventors: Gang Ning, Santa Clara, CA (US); Paul A. Martinez, Morgan Hill, CA (US); Amanda R. Rainer, Sunnyvale, CA (US); Won Seop Choi, Cupertino, CA (US); Gemin Li, Pleasanton, CA (US); Zhong-Qing Gong, Belmont, CA (US); Shawn X. Arnold, Santa Cruz, CA (US)

(73) Assignee: Apple Inc., Cupertino, CA (US)

(21) Appl. No.: 15/694,726

(22) Filed: Sep. 1, 2017

Related U.S. Application Data
(60) Provisional application No. 62/382,739, filed on Sep. 1, 2016.

(51) Int. Cl. H01G 4/30; H01G 4/008; H01G 4/232; H01G 4/12; H05K 1/18

(52) U.S. Cl. CPC H01G 4/30; H01G 4/008; H05K 2201/10015; H01G 4/1209; H05K 1/18; H01G 4/232

(57) ABSTRACT

Passive component structures that may save space, are readily manufactured, and are easy to use. In one example, a passive component structure may include two capacitors, each formed as a group of plates separate and apart from the other. The two groups of plates may have a spacing layer between them.

### CROSS-REFERENCES TO RELATED APPLICATIONS

This claims the benefit of U.S. provisional patent application No. 62/382,739, filed Sep. 1, 2016, which is incorporated by reference.

### BACKGROUND

Electronic devices, circuits, and modules, such as system-in-a-package (SIP) modules may include one or more integrated circuits and often include several passive components, such as capacitors, resistors, and inductors. The integrated circuits and passive components may be placed on a printed circuit board, flexible circuit board, or other appropriate substrate in the electronic devices, circuits, or modules.

These passive components may be used for various purposes. For example, they may be used to filter power supplies that are either provided to the electronic devices, circuits, or modules from an external source or generated on the electronic devices, circuits, or modules by voltage regulators or other circuits. They may be used to filter or AC couple signals. These passive components may be used to compensate amplifiers and other active circuits, they may be used as integrators, in timing circuits or oscillators, or they may be used for other purposes.

Accordingly, there may be several passive components on a board in these electronic devices, circuits, or modules. These passive components may consume a great deal of area on a printed circuit board, flexible circuit board, or other appropriate substrate. This area may require an electronic device, circuit, or module to be larger in size, have a reduced functionality, or a combination thereof.

Also, since such large numbers of these components may be used, it may be desirable that they be readily manufactured. With the tremendous volumes of units being made, even small decreases in yields may add up to large losses in terms of numbers of units. Also, since margins may be relatively low for these passive components, these small yield losses may affect profitability.

Moreover, since so many of these devices may be placed on a printed circuit board, flexible circuit board, or other appropriate substrate in these electronic devices, circuits, or modules, it may be desirable that they be easy to use. That is, it may be desirable that they be easy to use in the manufacturing of the electronic devices, circuits, or modules.

Thus, what is needed are passive component structures that may save space, are readily manufactured, and are easy to use.

### SUMMARY

Accordingly, embodiments of the present invention may provide passive component structures that may save space, are readily manufactured, and are easy to use.

An illustrated embodiment of the present invention may provide a passive component structure that is a capacitor structure, such as a multilayer ceramic capacitor, that saves space by stacking more than one capacitor in a single unit. This capacitor structure may include more than one capacitor, where each capacitor is a group or set of parallel plates. The group or set of plates for a capacitor may be adjacent plates, where only plates for that capacitor are included in the group or set. The groups or sets of adjacent parallel plates that form a capacitor may include alternating plates connected to different terminals. For example, one such capacitor structure may include a first capacitor formed of a first group or set of adjacent plates stacked above a second capacitor formed of a second group or set of adjacent plates. Alternating plates in the first capacitor may connect to a first terminal and a second terminal, while alternating plates in the second capacitor may connect to a third terminal and a fourth terminal. In various embodiments of the present invention, two terminals, such as the first and third terminals may be connected to each other in the capacitor structure. This and other capacitor structures may include more than two capacitors. For example, capacitor structures consistent with embodiments of the present invention may include three, four, or more capacitors. These capacitors may be connected internally in the capacitor structures in parallel, series, or another arrangement. This may allow multiple capacitors in a single unit to be connected in parallel. This may be of particular use in bypassing or decoupling power supply voltages.

These and other embodiments of the present invention may provide a passive component structure that is readily manufactured. Specifically, capacitor structures may be formed by forming conductive plates with intervening dielectric material. This dielectric material may be placed between and at least partially around the plates of the capacitors. The dielectric between and around the plates may be a ceramic or other material. The ceramics that may be used include class 1 or class 2 ceramics. Examples of such class 1 type of ceramics that may be used as dielectric include C0G, U2J, and others. Examples of such class 2 ceramics that may be used as a dielectric include X5R, X7R, X6S, X7S, and others.

In these and other embodiments of the present invention, a spacing layer may be formed or placed between groups of plates of the various capacitors, or above or below groups of plates of the capacitors. This spacing layer may be formed of a dielectric, it may be a void or cavity, or it may be formed of other material or materials. This dielectric may be the same or different than the dielectric between and around the plates of the capacitors. The dielectric may be a ceramic or other material. The ceramics that may be used include class 1 or class 2 ceramics. Examples of such class 1 type of ceramics that may be used as dielectric include C0G, U2J, and others. Examples of such class 2 ceramics that may be used as a dielectric include X5R, X7R, X6S, X7S, and others.

In these and other embodiments of the present invention, the capacitor plates may be formed of, or plated or coated with, a conductive material or combination of materials. For example, the capacitor plates may be formed or plated or coated using copper, a copper alloy, nickel, a nickel alloy, aluminum, tin, gold, silver, palladium, or other material or combination thereof.

In these and other embodiments of the present invention, the terminals may be external electrodes. These external electrodes may be glass, frit, or other type of ceramic composite. The ceramic composite may include copper, nickel, or one of their alloys, or other material or combination of materials. They may be coated with nickel, tin, copper, or one of their alloys, or other material or combination of materials. One or more optional intermediate conductive layers formed of one or more of these materials may be included.

These and other embodiments of the present invention may provide passive component structures that are easy to use. For example, a passive component structure according to an embodiment of the present invention may include end terminals and side terminals. An end terminal may partly, substantially, or completely cover an end of the passive component structure. An end terminal may extend from an end of the passive component structure along one or more of the top, bottom, and sides of the passive component structure. In these and other embodiments of the present invention, an end terminal may be located primarily or exclusively on an end, bottom, side, or top of the passive component structure. A side terminal may partly or substantially cover a side of the passive component structure. A side terminal may extend from a side of the passive component structure along one or more of the top, bottom, ends, and opposing side of the passive component structure. In these and other embodiments of the present invention, a side terminal may be located primarily or exclusively on a bottom, side, or top of the passive component structure. One or all of these terminals may physically and electrically connect, for example by soldering or sintering, to solder pads or contacts on a printed circuit board, flexible circuit board, or other appropriate substrate. One or all of these terminals may physically and electrically connect, for example by soldering or sintering, to contacts on an active device, passive device, passive component structure, or other type of component.

In these and other embodiments of the present invention, the terminals or external electrodes may have inductive, capacitive, and resistive properties. The inductance, capacitance, and resistance associated with a terminal or external electrode may be referred to as parasitic inductors, capacitors, and resistors. In various embodiments of the present invention, these parasitic components may be minimized, decreased, or increased in a passive component structure, depending on the components and their expected use. These parasitic components may be positioned or located where they may help in varying the performance of a passive component structure controlled manner.

In one example, a capacitor structure may include two capacitors, where the two capacitors are of a different size. These capacitors may be used as a filter to decouple a power supply. For improved filtering, it may be desirable that a first, smaller capacitor have a lower equivalent series inductance. Accordingly, the first, smaller capacitor may be located on the bottom of a capacitor structure where it may be closer to contacts or solder pads of a printed circuit board. This may result in a shorter length of terminal or external electrode for the first, smaller capacitor. This shorter length may result in a reduced equivalent series inductance. To further reduce this inductance, plates of the first, smaller capacitor may connect to two or more terminals. In this example, a second, larger capacitor may be located above the first, smaller capacitor such that it has a higher equivalent series inductance. This inductance may be tuned by adjusting a width of the spacing layer between the first, smaller capacitor and the second, larger capacitor. This inductance may also be adjusted by adjusting the thickness and area of its terminals. The effective inductance, as well as capacitance of the first and second capacitors, may also be adjusted by the quantity and print patterns of electrode layers or plates used in each capacitor. The resulting passive component structure with two capacitors of different sizes and an intervening inductance may be well-suited to power supply filtering.

In this example, an impedance curve of the resulting passive component structure may be characterized by multiple distinctive self-resonance frequencies (SRF). These SRFs may be positioned or dictated by the inductance and capacitance values of the capacitors stacked in the package. In addition, the location of the SRFs may be tuned or shifted in frequency by adjusting an effective capacitance, inductance, or both, of individual capacitors in a package. For example, this may be done by adjusting the quantity of layers and electrode patterns in some or all of the capacitors stacked in the package.

These and other embodiments of the present invention may provide other types of capacitive structures. For example, a matched pair of capacitors may be formed by alternating plates of a first capacitor and a second capacitor. For example, a ground plate may be over a plate for a first capacitor, which may be over a ground plate, which may be over a plate for a second capacitor, which may be over a ground plate, and so on. These two capacitors may be a set or group of plates separate from a third capacitor, which may be a separate group of adjacent plates. This structure may yield a capacitor structure having a matched pair of capacitors and a third capacitor in a single unit.

In these and other embodiments of the present invention, other types of passive components may be included in a passive component structure. For example, one or more resistors may be included in a passive component structure. These resistors may be made of a ceramic, they may be formed using thin or thick film techniques, they may be formed by etching or printing one or more plates, or they may be formed in other ways of other materials. Inductors may be formed using lengths of external electrodes. Inductors may also be formed by etching or printing spiral or other shapes in one or more plates.

Embodiments of the present invention may provide capacitor structures and other passive component structures that may perform various functions in electronic devices, circuits, and modules, such as SIP modules. For example, the capacitor structures may be used to filter power supplies that are either provided to the electronic devices, circuits, or modules from an external source, or generated on the electronic devices, circuits, or modules by voltage regulators or other circuits. They may be used to filter or AC-couple signals. These passive components may be used to compensate amplifiers and other active circuits. They may be used as integrators or in timing circuits or oscillators, or they may be used for other purposes. In this and other examples herein, the passive component structures may be a multilayer ceramic capacitor or other type of passive component structure.

These and other embodiments of the present invention may provide multilayer ceramic capacitors (MLCCs) and other passive component structures that may be packaged in a SIP module or other module or device. When these capacitors have a voltage applied to them, they may expand or contract due to the inverse-piezoelectric or electrostrictive effects. When the applied voltage changes, these effects may modulate one or more surfaces of a SIP module (that is, make one or more surfaces vibrate), essentially causing the SIP module to act as a speaker and produce an audible sound or acoustic noise. Over time, this vibration may also exacerbate and enlarge naturally occurring gaps between the capacitors and any molding or potting compounds used to encapsulate the SIP module. These gaps may then become moisture ingress paths that may corrode or damage the capacitor. This moisture may also cause dendrite growth that may lead to the terminals of the capacitors becoming shorted together.

These and other embodiments of the present invention may mitigate these inverse-piezoelectric or electrostrictive effects by coating the capacitors with an elastomer or other pliable or pliant material. Other circuits or components in the SIP module may likewise be coated with an elastomer or other material. The elastomer-coated capacitors and components may then be encapsulated with a molding compound or potting material. The pliable elastomer may absorb vibration or modulation caused by the capacitors, thereby reducing the amount of acoustic noise generated. The elastomer may also act as a moisture barrier, particularly when a hydrophobic elastomer is used.

In these and other embodiments of the present invention, various elastomers may be used. These may be monomers, or a combination of monomers, such as a dipolymer or a terpolymer. Layers of different elastomers may also be used. The elastomers may belong to an elastomer family such as butadiene rubber, butyl rubber, ethylene propylene rubber, isoprene rubber, natural rubber, silicone rubber, tetrafluoroethylene propylene rubber, polyurethane rubber, nitrile rubber or styrene butadiene rubber, or others. Functionally modified elastomers may also be used in these and other embodiments of the present invention. Additives, such as a solvent, plasticizer and other agents may be added in the elastomer to achieve a desired viscosity, rheology, or other physical properties or characteristic.

In these and other embodiments of the present invention, the elastomers used may have various properties. For example, they may be hydrophobic to reduce possible moisture damage. They may have a glass transition temperature or melting point (if crystalline) of −150 C to −25 C. The elastomer may have a density of 0.8 to 1.4 g/cm³ and a Young's modulus between 0.0001 and 0.1 GPa. The thickness of the elastomer may be between 1 micron and 50 percent of the height of the SIP module, though it may have a greater or lesser thickness.

In these and other embodiments of the present invention, the elastomer, with or without additives, may be applied as a liquid to a capacitor. The elastomer may be thermally or UV cured, or cured in some other manner. A molding compound may then encapsulate the capacitor and other circuits or components to form the SIP module.

In these and other embodiments of the present invention, an elastomer or other elastic substrate may be used to protect a printed circuit board from the compression and expansion of these capacitors due to the inverse-piezoelectric or electrostrictive effects. Specifically, an elastic substrate may be used between a capacitor, such as the multilayer ceramic capacitors disclosed above, and a printed circuit board or other substrate. This may protect printed circuit board contacts from stress and may reduce acoustic noise. These substrates may be attached to a board, and then a capacitor may be placed on the substrate. In these and other embodiments of the present invention, the substrate may be attached to a capacitor, and then the substrate and capacitor may be attached to the board. These attachments may be done by welding, regular soldering, laser soldering, hot bar process, or other appropriate technique. The substrates may include an elastic core with conductive pads on its top and bottom, where the conductive pads are connected.

In these and other embodiments of the present invention, the substrate may include one or more elastomers, or elastomer wrapped or coated thermosetting or thermoplastic material. The conductive pads may be cladded or glued metal foil, they may be formed by plating, sputtering, vapor deposition, electroless plating, or other appropriate technique. Interconnect between the pads may be formed by through-holes, edge plating or sputter, or other appropriate technique. The pads may be coated with gold, tin, a tin alloy, or other material.

In these and other embodiments of the present invention, an elastomer or other elastic substrate may be used to absorb a certain degree of mechanical energy from the compression and expansion of these capacitors due to the inverse-piezoelectric or electrostrictive effects. Specifically, an elastic substrate may be used between a capacitor, such as the multilayer ceramic capacitors and other passive components disclosed above, and a printed circuit board or other substrate. This may protect printed circuit board contacts from stress and may reduce acoustic noise. These substrates may be attached to a board, and then a capacitor may be placed on the substrate. In these and other embodiments of the present invention, the substrate may be attached to a capacitor, and then the substrate and capacitor may be attached to the board. These attachments may be done by welding, regular soldering, laser soldering, hot bar process, or other appropriate technique. The substrates may include an elastic core with conductive pads on its top and bottom, where the conductive pads are connected to each other, either by side plating, through-holes, vias, or other path.

In these and other embodiments of the present invention, the substrate may include one or more elastomers, an elastomeric layer wrapped or coated thermosetting or thermoplastic material, or other materials or combination of materials. The conductive pads may be cladded or glued metal foil, they may be formed by plating, sputtering, vapor deposition, electroless plating, or other appropriate technique. Interconnect between the pads may be formed by through-holes, edge plating or sputtering, or other appropriate technique. The pads may be coated with gold, tin, a tin alloy, or other material.

In these and other embodiments of the present invention, various elastomers may be used for the substrates. These may be monomers, or a combination of monomers, such as a dipolymer or a terpolymer. Layers of different elastomers may also be used. The elastomers may be belong to an elastomer family such as butadiene rubber, butyl rubber, ethylene propylene rubber, isoprene rubber, natural rubber, silicone rubber, tetrafluoroethylene propylene rubber, polyurethane rubber, nitrile rubber or styrene butadiene rubber, or others. Functionally modified elastomers may also be used in these and other embodiments of the present invention. Additives, such as a solvent, plasticizer and other agents may be added in the elastomer to achieve a desired viscosity, rheology, or other physical properties or characteristic.

In these and other embodiments of the present invention, the elastomers used may have various properties. For example, they may be hydrophobic to reduce possible moisture damage. They may have a glass transition temperature or melting point (if crystalline) of −150 C to −25 C. The elastomer may have a density of 0.8 to 1.4 g/cm³ and a Young's modulus between 0.0001 and 0.1 GPa. The shape of the substrate can be square, rectangle, oval, or it may have a different shape. The ratio between the height and the periphery may be less than 30 percent, it may be 30 percent, or it may be greater than 30 percent. The thickness of the substrate may be less than 10 microns, between 10 microns and 3 millimeters, or more than 3 millimeters.

In the above examples, embodiments of the present invention may provide multilayer ceramic capacitors and other passive devices, as well as methods and structures for incorporating these components in a SIP module or other type of device. These and other embodiments of the present invention may further provide enhancements and improvements to other types of components. For example, these and other embodiments of the present invention may provide improvements to electrolytic capacitors. These and other embodiments of the present invention may also provide improved electrolytic capacitors and their method of manufacture.

In the above examples, elastomers may be used to block moisture ingress. This use of elastomers may extend to preventing or limiting moisture ingress in electrolytic capacitors and other types of devices. In these and other embodiments of the present invention, elastomers may be used as coatings for lead frames inside electrolytic capacitors. These pliable coatings may be initially compressed, and may later expand to fill a gap between the lead frame and the remainder of the capacitor that may result due to environmental stress and changes. The lead frame itself may also be modified to further improve the resulting seal. The thickness of these coatings may be between 1 micron and 50 percent of the package height. The coatings may have a length between 1 micron and 50 percent of the package length. The coatings may be applied either as part of the lead frame manufacturing or the capacitor manufacturing.

In these and other embodiments of the present invention, various elastomers may be used. These may be monomers, or a combination of monomers, such as a dipolymer or a terpolymer. Layers of different elastomers may also be used. The elastomers may be belong to an elastomer family such as butadiene rubber, butyl rubber, ethylene propylene rubber, isoprene rubber, natural rubber, silicone rubber, tetrafluoroethylene propylene rubber, polyurethane rubber, nitrile rubber or styrene butadiene rubber, or others. Functionally modified elastomers may also be used in these and other embodiments of the present invention. Additives, such as fillers or foaming agents can be added to adjust elasticity, resilience, tortuosity, pore size distribution density, molecular weight, surface tension and other physical properties.

In these and other embodiments of the present invention, the elastomers used may have various properties. For example, they may be hydrophobic to reduce possible moisture damage. The elastomers may have a glass transition temperature or melting point (if crystalline) of −150 C to −25 C. The elastomer may have a density of 0.8 to 1.4 g/cm3. Where the coating is porous, the density may be between 0.025 to 0.8 g/cm³.

Unfortunately, these lead frames consume space inside a capacitor. Also, the bending and trimming of these lead frames may mechanically overstress a capacitor, thus leading to yield loss, thereby wasting resources. Accordingly, these and other embodiments of the present invention may provide capacitors that do not employ a lead frame. Instead, interconnects between internal capacitor elements and external contacts or terminals are provided using applied metal, metal alloy, conductive adhesive, or other material.

Embodiments of the present invention may provide capacitor structures that may be used in various types of devices, such as portable computing devices, tablet computers, desktop computers, laptops, all-in-one computers, wearable computing devices, cell phones, smart phones, media phones, storage devices, cases, covers, keyboards, pens, styluses, portable media players, navigation systems, monitors, power supplies, adapters, remote control devices, chargers, and other devices.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a passive component structure according to an embodiment of the present invention;

FIG. 2 illustrates a passive component structure according to an embodiment of the present invention;

FIG. 3 is a schematic of the passive component structure of FIG. 2;

FIG. 4 is a simplified schematic of the passive component structure of FIG. 2;

FIG. 5 illustrates the impedance over frequency for a passive component structure according to an embodiment of the present invention;

FIG. 6 illustrates a cross-section of a passive component structure according to an embodiment of the present invention;

FIG. 7 illustrates another cross-section of a passive component structure according to an embodiment of the present invention;

FIG. 8 illustrates a top view of a capacitor electrode plate according to an embodiment of the present invention;

FIG. 9 illustrates a top view of another capacitor electrode plate according to an embodiment of the present invention;

FIG. 10 illustrates a top view of another capacitor electrode plate according to an embodiment of the present invention;

FIG. 11 illustrates a top view of a passive component structure according to an embodiment of the present invention;

FIG. 12 illustrates the layers of the passive component structure of FIG. 11;

FIG. 13 illustrates a top view of a passive component structure according to an embodiment of the present invention;

FIG. 14 illustrates the layers of the passive component structure of FIG. 13;

FIG. 15 illustrates a top view of a passive component structure according to an embodiment of the present invention;

FIG. 16 illustrates the layers of the passive component structure of FIG. 15;

FIGS. 17A-17C illustrate a method of manufacturing a portion of a SIP module according to an embodiment of the present invention;

FIGS. 18A-18B illustrate another method of manufacturing a SIP module according to an embodiment of the present invention;

FIGS. 19A-19B illustrate another method of manufacturing a SIP module according to an embodiment of the present invention;

FIGS. 20A-20B illustrate an elastic substrate according to an embodiment of the present invention;

FIG. 21 illustrates another elastic substrate according to an embodiment of the present invention;

FIG. 22 illustrates another elastic substrate according to an embodiment of the present invention;

FIGS. 23A-23B illustrate a coating on a lead frame of an electrolytic capacitor according to an embodiment of the present invention;

FIG. 24 illustrates a capacitor according to an embodiment of the present invention;

FIGS. 25A-25D, 26A-26C, 27A-27C, and 28A-28B illustrate a method of forming the capacitor of FIG. 24;

FIG. 29 illustrates a capacitor according to an embodiment of the present invention; and

FIGS. 30A-30D, 31A-31C, 32A-32C, and 33A-33B illustrate a method of forming the capacitor of FIG. 29.

### DESCRIPTION OF EXEMPLARY EMBODIMENTS

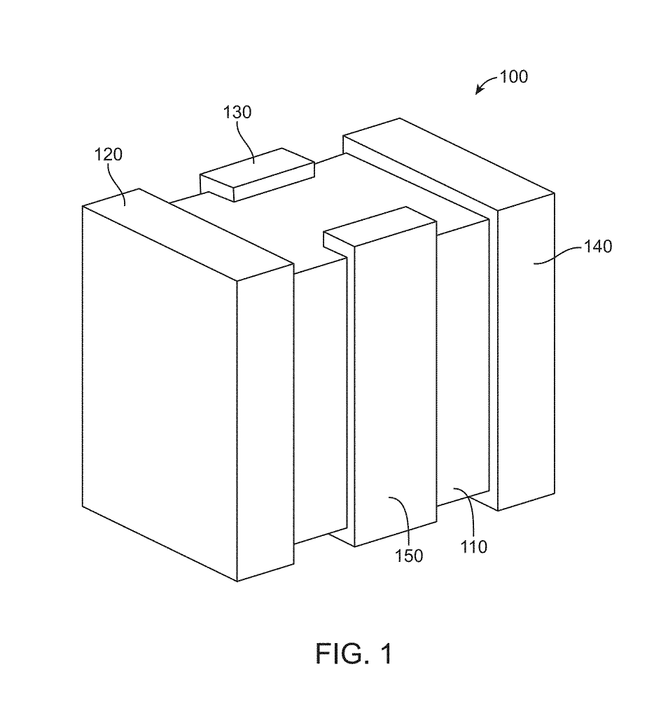

FIG. 1 illustrates a passive component structure according to an embodiment of the present invention. This figure, as with the other included figures, is shown for illustrative purposes and does not limit either the possible embodiments of the present invention or the claims.

Passive component structure 100 may include a number of layers forming passive components in a structure body 110. Passive component structure 100 may include end terminals 120 and 140 and side terminals 130 and 150. One or all of terminals 120, 130, 140, and 150 may physically and electrically connect, for example by soldering, to solder pads or conductively glued to contacts on a printed circuit board, flexible circuit board, or other appropriate substrate. One or all of terminals 120, 130, 140, and 150 may physically and electrically connect, for example by soldering, to contacts on another active device, passive device, passive component structure, or other type of component. In this and other examples herein, the passive component structures, such as passive component structure 100, may be a multilayer ceramic capacitor or other type of passive component structure.

In these and other embodiments of the present invention, structure body 110 may be formed using a dielectric material. The dielectric material may be a ceramic or other material. The ceramics that may be used include class 1 or class 2 ceramics. Examples of such class 1 type of ceramics that may be used as dielectric include C0G, U2J, and others. Examples of such class 2 ceramics that may be used as a dielectric include X5R, X7R, X6S, X7S, and others.

In these and other embodiments of the present invention the terminals 120, 130, 140, and 150 may be external electrodes. These external electrodes or terminals may be glass, frit, or other type of ceramic composite. The ceramic composite may include copper, nickel, or one of their alloys, or other material or combination of materials. They may be coated with nickel, tin, copper, or one of their alloys, or other material or combination of materials. An optional intermediate conductive layer formed of one or more of these materials may be included.

In these and other embodiments of the present invention, passive component structure 100 may include one or more passive components. These components may be formed on layers that are stacked in passive component structure 100. An example is shown in the following figure.

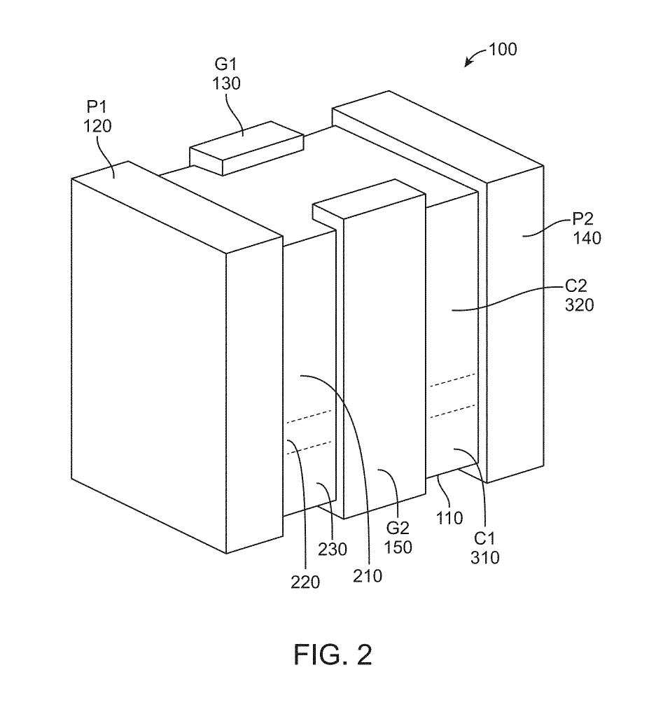

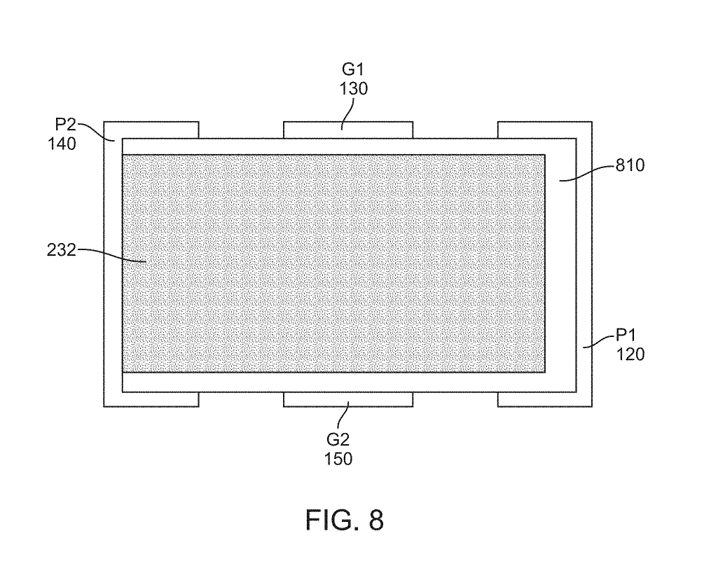

FIG. 2 illustrates a passive component structure according to an embodiment of the present invention. As before, passive component structure 100 may include a number of layers forming passive components in a structure body 110. These layers may include alternating conductive plates and dielectric layers (as shown in FIGS. 8-10). Passive component structure 100 may include end terminals 120 and 140 and side terminals 130 and 150. Plates may be extended to one or more ends of passive component structure 100 to form an electrical connection with either or both end terminals 120 and 140, and the plates may be extended to one or more sides of passive component structure 100 to form an electrical connection with either or both side terminals 130 and 150. Plates may be pulled back from one or more ends of passive component structure 100 to isolate the plates from either or both end terminals 120 and 140, and the plates may be pulled back from one or more sides of passive component structure 100 to isolate the plates from either or both side terminals 130 and 150. Details of this are shown in FIGS. 8-10 below.

In this example, passive component 100 may include a first capacitor C1 310 formed of layers in region 230 and a second capacitor C2 320 formed of layers in region 210. In this way, the two separate capacitors C1 310 and C2 320 may be formed as a single unit. A spacing layer or region 220 may be included between region 230 and region 210. Capacitors C1 310 and C2 320 may each have a first node and a second node. End terminals P1 120 and P2 140 may connect to plates for the first nodes of each of the capacitors C1 310 and C2 320, respectively, while the side terminals G1 130 and G2 150 may connect to plates for the second nodes of both capacitors C1 310 and C2 320.

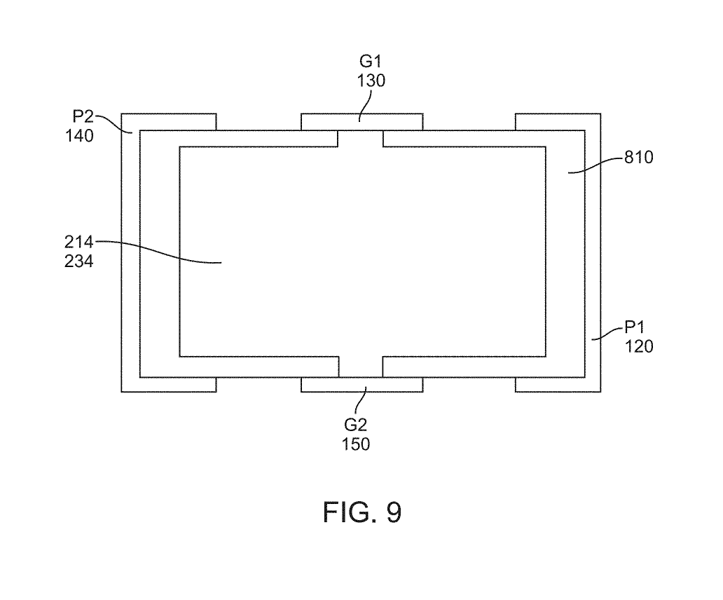

More specifically, capacitor C1 310 may include a first node connected to end terminal P1 120 and to first electrode plates 232 (shown in FIG. 8) in region 230. Capacitor C1 310 may further include a second node connected to side terminals G1 130 and G2 150 and to second plates 234 (show in FIG. 9) in region 230. These connections may be formed by extending edges of first electrode plates 232 in region 230 to an end of passive component structure 100 where they may contact end terminal P1 120. The other edges of first electrode plates 234 may be pulled back from the sides and other end of passive component structure 100 to avoid connecting to end terminal P2 140 or side terminals G1 130 or G2 150. Similarly, edges of second plates 234 may extend to sides of passive component structure 100 where they may contact side terminals G1 130 and G2 150, while their other edges may be pulled back from the ends of passive component structure 100 to avoid contact with end terminals P1 120 and P2 140. First electrode plates 232 and second plates 234 in region 230 may be alternating plates, that is, they may be positioned such that at least one of first electrode plates 232 is adjacent to and between two second plates 234 and at least one of second plates 234 is adjacent to and between two first electrode plates 232.

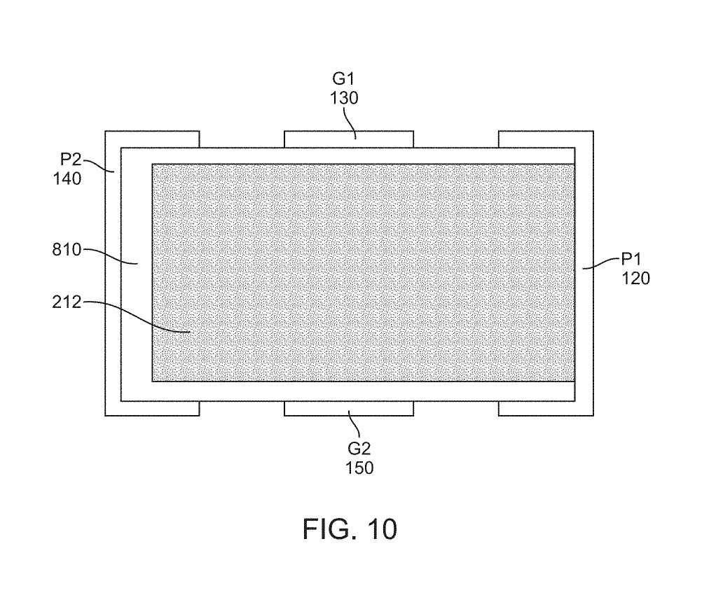

Similarly, capacitor C2 320 may include a first node connected to end terminal P2 140 and to first electrode plates 212 (shown in FIG. 10) in region 210. Capacitor C2 320 may further include a second node connected to side terminals G1 130 and G2 150 and to second electrode plates 214 (shown in FIG. 9) in region 210. These connections may be formed by extending edges of first electrode plates 212 in region 210 to an end of passive component structure 100 where they may contact end terminal P2 140. The other edges of first electrode plates 214 may be pulled back from the sides and other end of passive component structure 100 to avoid connecting to end terminal P1 120 or side terminals G1 130 or G2 150. Similarly, second electrode plates 214 may extend to sides of passive component structure 100 where they may contact side terminals G1 130 and G2 150, while their other edges may be pulled back from the ends of passive component structure 100 to avoid contact with end terminals P1 120 and P2 140. First electrode plates 212 and the second electrode plates 214 in region 210 may be alternating plates, that is, they may be positioned such that at least one of first electrode plates 212 is adjacent to and between two second electrode plates 214 and at least one of second electrode plates 214 is adjacent to and between two first electrode plates 212. Further details are shown in the figures below.

This passive component structure 100 may be a capacitor structure that may include two capacitors, C1 310 in region 230 and C2 320 in region 210, where the two capacitors C1 310 and C2 320 may have a different size. This may be of particular use as a filter to decouple or filter a power supply. For improved filtering, it may be desirable that a first, smaller capacitor have a lower equivalent series inductance. Accordingly, the first, smaller capacitor C1 310 in region 230 may be located on the bottom of a capacitor structure where it will be closer to solder pads or contacts of a printed circuit board (not shown, but under passive component structure 100 as illustrated.) This may result in a shorter length of terminal or external electrode for the first, smaller capacitor C1 310. This shorter length may result in a reduced equivalent series inductance. To further reduce inductance, plates of the first, smaller capacitor may connect to two or more terminals. In this example, a second, larger capacitor C2 320 in region 210 may be located above the first, smaller capacitor such that it has a higher series inductance. This inductance may be tuned by adjusting the spacing provided by the spacing layer 220 between the first, smaller capacitor C1 310 in region 230 and the second, larger capacitor C2 320 in region 210. This inductance may also be adjusted by adjusting the thickness and area of its terminals. The effective inductance, as well as capacitance of the first and second capacitors, may also be adjusted by the quantity and print patterns of electrode layers or plates used in each capacitor.

In other embodiments of the present invention, passive component structures, such as passive component structure 100, may include more than two capacitors. For example, capacitor structures consistent with embodiments of the present invention may include three, four, or more capacitors. These capacitors may be connected internally in the capacitor structures in parallel, series, or some other arrangement. This may allow multiple capacitors in a single unit to be connected in parallel. This may be of particular use in bypassing or decoupling power supply voltages.

In this example, passive component structure 100 may include end terminals P1 120 and P2 140 and side terminals G1 130 and G2 150. End terminals P1 120 and P2 140 may each cover an end of passive component structure 100 and extend along its top, bottom, and sides. Side terminals G1 130 and G2 150 may run along sides of passive component structure 100 and partly extend along its top and bottom. In these and other embodiments of the present invention, an end terminal, such as end terminals P1 120 and P2 140, may partly, substantially, or completely cover an end of the passive component structure. An end terminal may extend from an end of the passive component structure along one or more of the top, bottom, and sides of the passive component structure. In these and other embodiments of the present invention, an end terminal may be located primarily or exclusively on an end, bottom, side, or top of the passive component structure. A side terminal, such as side terminals G1 130 and G2 150, may partly or substantially cover a side of the passive component structure. A side terminal may extend from a side of the passive component structure along one or more of the top, bottom, ends, and opposing side of the passive component structure. In these and other embodiments of the present invention, a side terminal may be located primarily or exclusively on a bottom, side, or top of the passive component structure. In these and other embodiments of the present invention these and other numbers of terminals positioned in these and other locations may be included on a passive component structure, such as passive component structure 100.

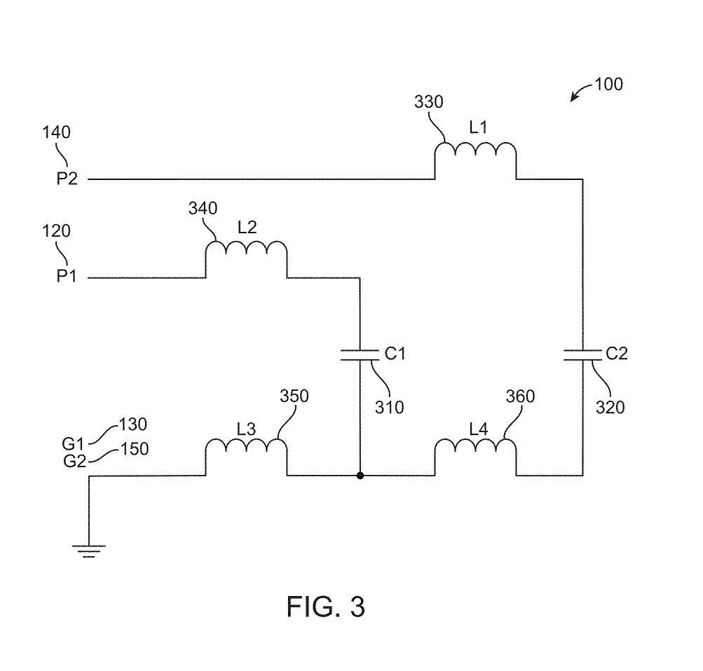

FIG. 3 is a schematic of the passive component structure of FIG. 2. This figure includes capacitors C1 310 and C2 320. Capacitor C1 310 may be formed of layers in region 230, while capacitor C2 320 maybe formed of layers in region 210 as shown in FIG. 2. In this example, capacitor C1 310 may have a relatively low value, while capacitor C2 320 may have a relatively high value. For example, capacitor C2 320 may have a capacitance value that is 10, 15, or 20 times the value of capacitor C1 310.

Some of the parasitic inductors that are associated with the terminals 120, 130, 140, and 150 as shown in FIG. 2 may be included here. Specifically, inductor L1 330 may model an inductance of terminal P2 120 from a bottom of passive component structure 100 to region 210 of passive component structure 100 as shown in FIG. 2. Similarly, inductor L2 340 may model an inductance of terminal P1 120 from a bottom of passive component structure 100 to region 230 of passive component structure 100 as shown in FIG. 2.

In FIG. 2, ground contact G1 130 may be electrically connected to ground contact G2 150 inside passive component structure 100. Inductor L3 350 may thus be the inductance through terminals G1 130 and G2 150 from region 230 to a bottom of passive component structure 100. Inductor L4 360 maybe the inductance through terminals G1 130 and G2 150 from region 210 to region 230 in passive component structure 100.

For simplification, an inductance associated with region 230, specifically L2 340, may be ignored. Also, the inductances associated with region 210 may be combined into a single inductance. Specifically, the inductance L1 330 of terminal P2 140 from the bottom of passive component structure 100 to region 210 and the inductances L4 360 and L3 350 through the ground terminals G1 130 and G2 150 to ground maybe combined. A simplified schematic is shown in the following figure.

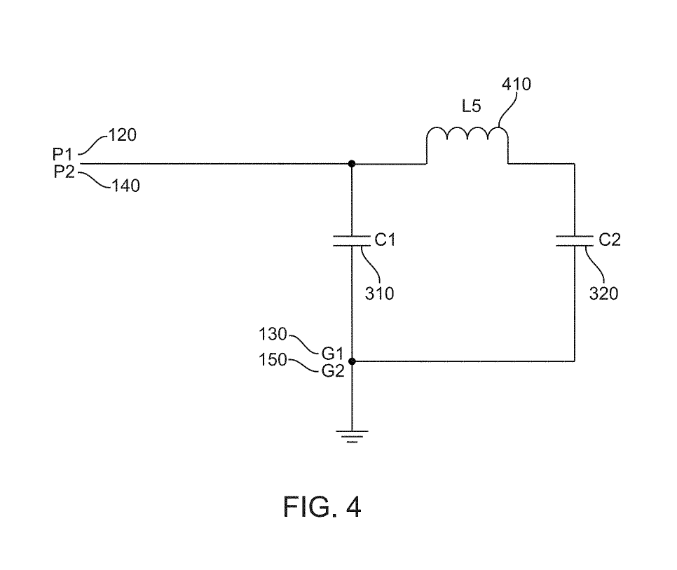

FIG. 4 is a simplified schematic of the passive component structure of FIG. 2. In this example, the schematic of FIG. 3 has been simplified by ignoring an inductance associated with region 230 (shown in FIG. 2), specifically L2 340, as shown in FIG. 3. Also, the remaining inductances L1 330, L4, 360, and L3 350 have been combined into a single inductance L5 410. Inductance 410 may be tuned by adjusting the spacing provided by the spacing layer 220 between the first, smaller capacitor C1 in region 230 and the second, larger capacitor C2 in region 210, as shown in FIG. 2. This inductance 410 may also be adjusted by varying the thickness and area of its terminals P2 140, G1 130, and G2 150.

Again, this tuned structure may be useful in decoupling or filtering power supply voltages. Specifically, this tuned structure may be useful in reducing an impedance of a power supply voltage over a range of frequencies. An example is shown in the following figure.

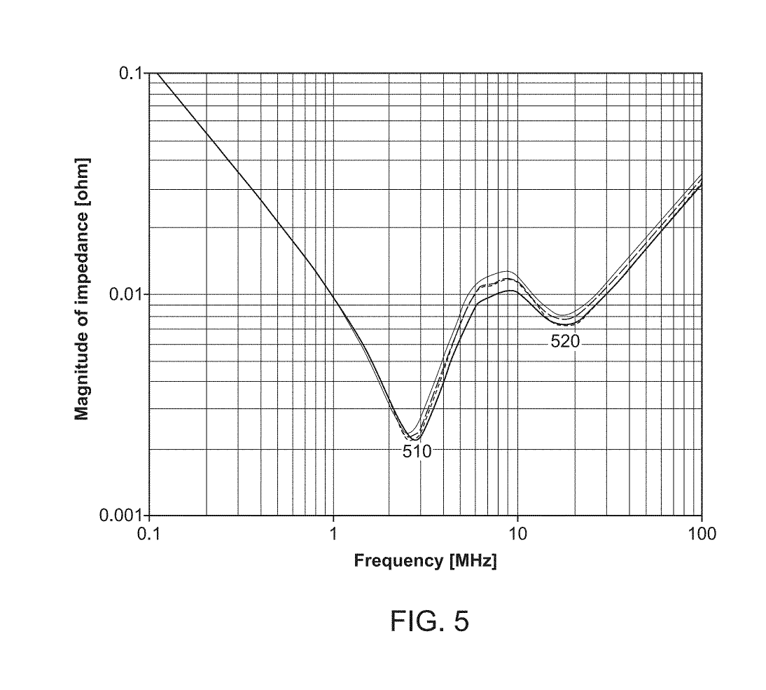

FIG. 5 illustrates the impedance over frequency for a passive component structure according to an embodiment of the present invention. In this example, the magnitude of the impedance provided by a passive component structure according to an embodiment of the present invention may have a first lower-frequency null 510 due to the larger capacitor C2. The smaller capacitor C1 may account for the higher-frequency null 520. The passive component structure of FIG. 2 may thus provide a low impedance for a power supply over a wide range of frequencies. This may be particularly true since capacitors in a passive component structure may be designed and arranged in a similar manner for improved scaling. That is, good low-impedance performance may be achieved when multiple capacitors are accurately scaled to each other and are connected in parallel.

In this example, the illustrated impedance curve of the passive component structure may be characterized by multiple distinctive self-resonance frequencies (SRF), shown here as nulls 510 and 520. These SRFs or nulls may be positioned or dictated by the inductance and capacitance values of the capacitors stacked in the package. In addition, the location of the SRFs or nulls may be tuned or shifted in frequency by adjusting the quantity of layers or plates and electrode patterns in some or all of the capacitors stacked in the package.

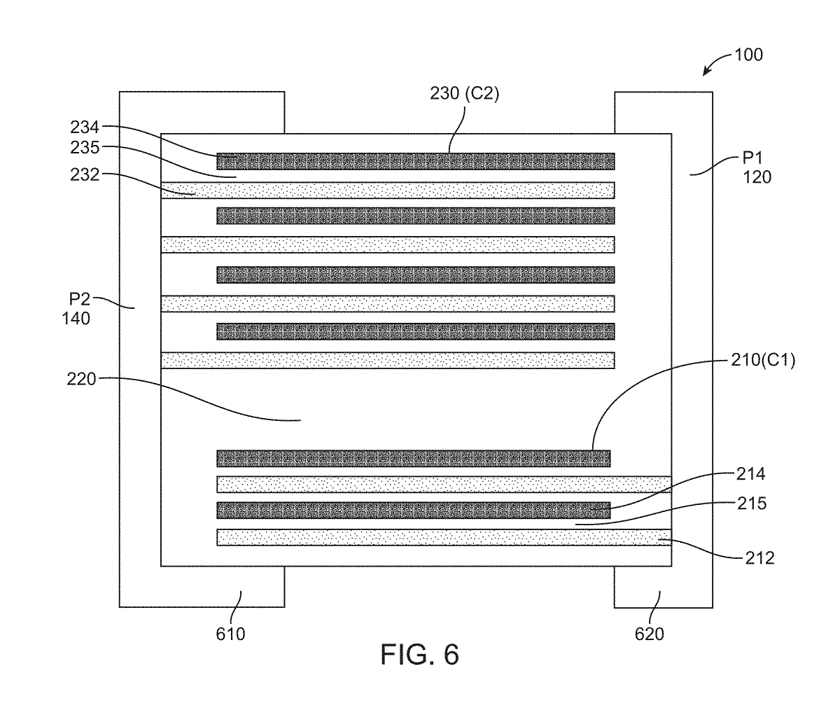

FIG. 6 illustrates a cross-section of a passive component structure according to an embodiment of the present invention. This figure may be a cross section of the passive component structure 100 of FIG. 2. In this example, a number of adjacent parallel electrode plates 232 and 234 in region 230 may form capacitor C2 (320 as shown in FIG. 2). Dielectric layers 235 may be positioned between adjacent parallel electrode plates 232 and 234 in region 230. Similarly, a number of adjacent parallel electrode plates 212 and 214 in region 210 may form capacitor C1 (310 as shown in FIG. 2). Dielectric layers 215 may also be positioned between adjacent parallel electrode plates 212 and 214 in region 210. Electrode plates 232 in region 230 may connect to terminal P2 140. Similarly, electrode plates 212 in region 210 may connect to terminal P1 120. That is, capacitor C2 230 may be formed by stacking an electrode plate 232, a dielectric layer 235, an electrode plate 234, another dielectric layer 235, then another electrode plate 232, and so on. Capacitor C1 210 may be formed by stacking an electrode plate 212, a dielectric layer 215, an electrode plate 214, another dielectric layer 215, then another electrode plate 212, and so on.

Spacing layer 220 may be positioned between parallel electrode plates in region 230 and parallel electrode plates in region 210. Spacing layer 220 may be formed using a dielectric material, it may be a void or a cavity, or it may be formed using other material or materials. The dielectric material may be a ceramic or other material. The ceramics that may be used include class 1 or class 2 ceramics. Examples of such class 1 type of ceramics that may be used as dielectric include C0G, U2J, and others. Examples of such class 2 ceramics that may be used as a dielectric include X5R, X7R, X6S, X7S, and others.

In these and other embodiments of the present invention, the parallel capacitor plates in regions 230 and 210 may be formed of, or plated or coated with, a conductive material or combination of materials. For example, the parallel capacitor electrode plates 212, 214, 232, and 234 in regions 230 and 210 may be formed, or plated or coated, using copper, a copper alloy, nickel, a nickel alloy, aluminum, tin, gold, silver, palladium, or other material or combination thereof. These parallel capacitor electrode plates may have intervening layers formed by a dielectric material that may be the same or different than the dielectric used to form spacing layer 220. These parallel capacitor electrode plates may also be at least partially surrounded by a dielectric material that may be the same or different than the dielectric used to form spacing layer 220. The dielectric material may be a ceramic or other material. The ceramics that may be used include class 1 or class 2 ceramics. Examples of such class 1 type of ceramics that may be used as dielectric include C0G, U2J, and others. Examples of such class 2 ceramics that may be used as a dielectric include X5R, X7R, X6S, X7S, and others.

In these and other embodiments of the present invention, portions 610 and 620 of terminals P1 120 and P2 140 may physically and electrically connect, for example by soldering or sintering, to solder pads or contacts on a printed circuit board, flexible circuit board, or other appropriate substrate (not shown). Either or both terminals P1 120 and P2 140 may physically and electrically connect, for example by soldering or sintering, to contacts on another active device, passive device, passive component structure, or other type of component (not shown).

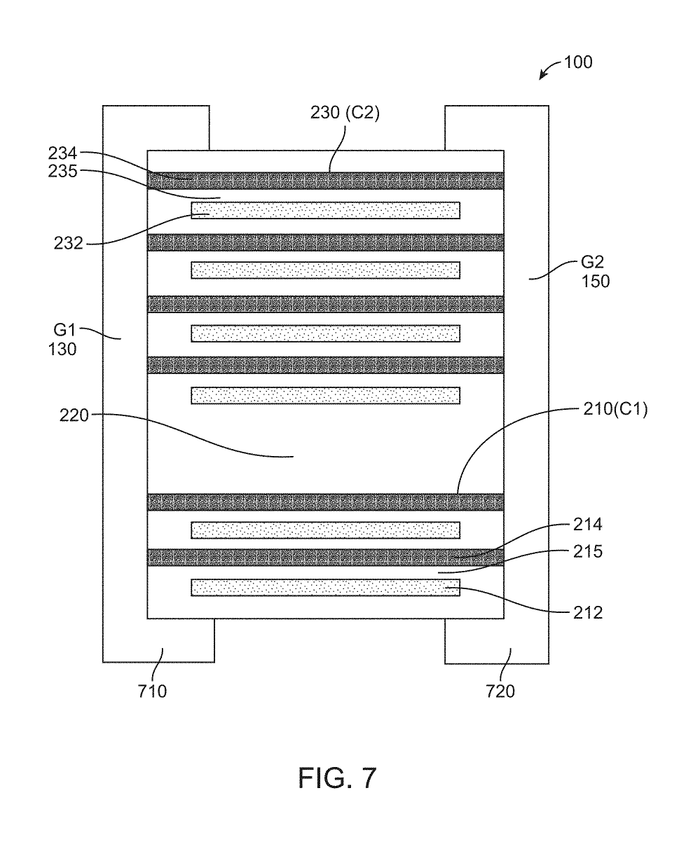

FIG. 7 illustrates another cross-section of a passive component structure according to an embodiment of the present invention. As with FIG. 6, this figure may be a cross section of the passive component structure 100 of FIG. 2. In this example, a number of adjacent parallel electrode plates 232 and 234 in region 230 may form capacitor C2 (320 as shown in FIG. 2). Similarly, a number of adjacent parallel electrode plates 212 and 214 in region 210 may form capacitor C1 (310 as shown in FIG. 2). Electrode plates 234 in region 230 may connect to terminals G1 130 and G2 150. Similarly, electrode plates 214 in region 210 may connect to terminals G1 130 and G2 150. Again, spacing layer 220 may be located between the two capacitors C1 310 and C2 320, dielectric layers 235 may also be positioned between electrode plates 232 and 234 in region 230, and dielectric layers 215 may be positioned between electrode plates 212 and 214 in region 210.

In these and other embodiments of the present invention, the capacitor structures may include more than one capacitor, where each capacitor is a group or set of parallel plates. The group or set of plates for a capacitor may be adjacent plates, where only plates for that capacitor are included in the group or set. For example, all the plates for capacitor C1 310 may be located in region 230 as adjacent plates, while all the plates for capacitor C2 320 may be located in region 210 as adjacent plates.

In these and other embodiments of the present invention, portions 710 and 720 of terminals G1 120 and G2 140 may physically and electrically connect, for example by soldering or sintering, to solder pads or contacts on a printed circuit board, flexible circuit board, or other appropriate substrate (not shown). Either or both terminals G1 120 and G2 140 may physically and electrically connect, for example by soldering or sintering, to contacts on another active device, passive device, passive component structure, or other type of component (not shown).

FIG. 8 illustrates a top view of a capacitor electrode plate according to an embodiment of the present invention. Capacitor electrode plate 232 may contact terminal P2 140. Capacitor electrode plate 232 may be at least partially surrounded by dielectric 810, which may be part of passive component structure body 110. Dielectric 810 may be a portion of dielectric layers 235 and may insulate capacitor electrode plate 232 from terminals G1 130, P1 120, and G2 150.

FIG. 9 illustrates a top view of another capacitor electrode plate according to an embodiment of the present invention. Capacitor electrode plate 214 (which may be the same as capacitor electrode plate 234) may contact terminals G1 130 and G2 150. Capacitor electrode plate 214 may be at least partially surrounded by dielectric 810, which may be part of passive component structure body 110. Dielectric 810 may be a portion of dielectric layers 235 or 215 and may insulate capacitor electrode plate 232 from terminals P1 120 and P2 140.

FIG. 10 illustrates a top view of a capacitor electrode plate according to an embodiment of the present invention. Capacitor electrode plate 212 may contact terminal P1 120. Capacitor electrode plate 212 may be at least partially surrounded by dielectric 810, which may be part of passive component structure body 110. Dielectric 810 may be a portion of dielectric layers 215 and may insulate capacitor electrode plate 212 from terminals G1 130, P2 140, and G2 150.

These capacitor plates may be varied to generate various passive component structures according to embodiments of the present invention. Examples are shown in the following figures.

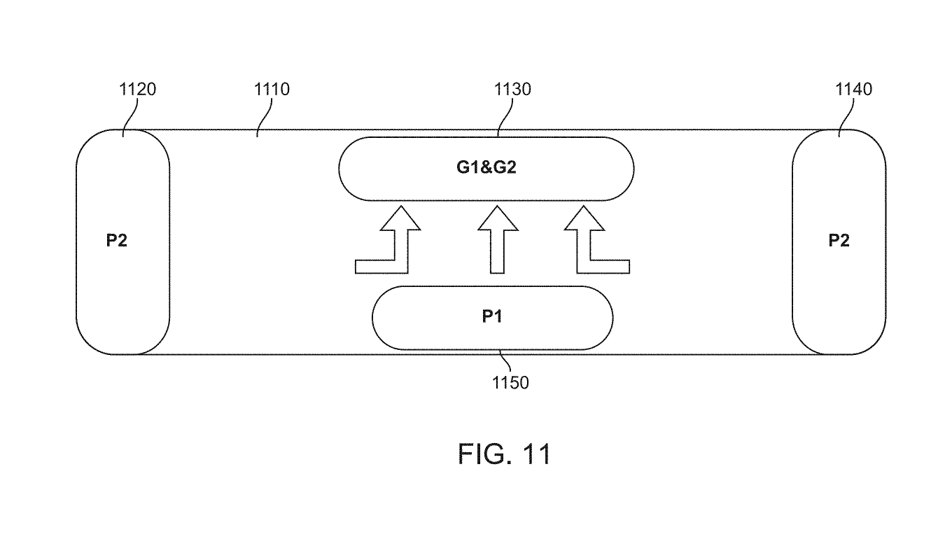

FIG. 11 illustrates a top view of a passive component structure according to an embodiment of the present invention. In this example, alternating capacitance plates for one capacitor are connected to two terminals, while two capacitors share a single terminal. This may help to reduce the inductance of the capacitor that is connected to the two terminals. Specifically, one capacitor has a first node connected to two terminals P2 1120 and 1140, another has a first node connected to terminal P1 1150, and they both have second nodes connected to terminal G1&G2 1130.

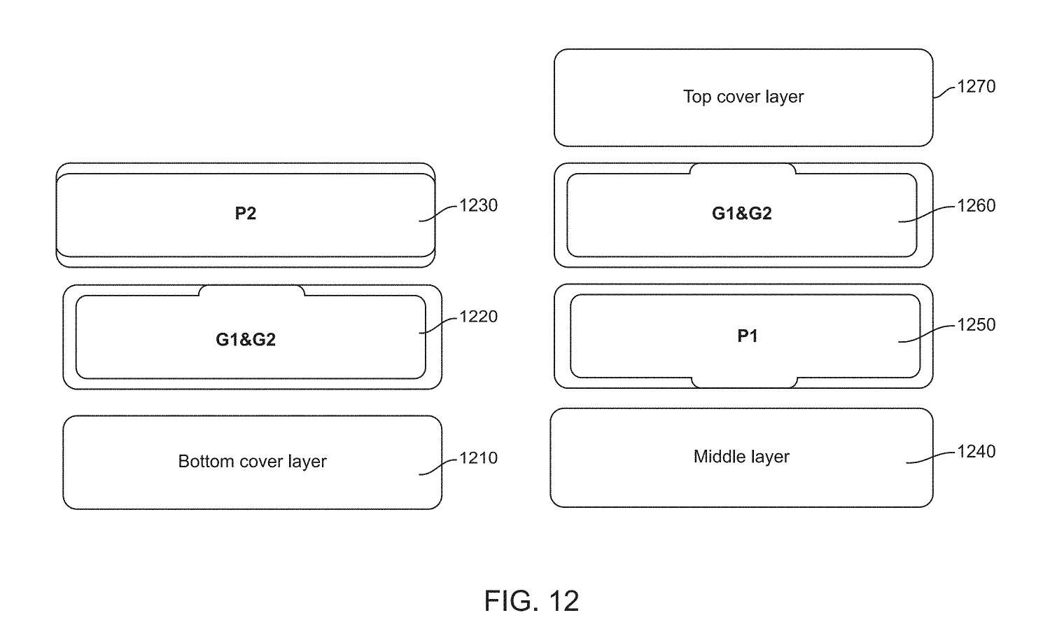

FIG. 12 illustrates the layers of the passive component structure of FIG. 11. A bottom cover layer 1210 may be formed. Alternating G1&G2 1220 and P2 1230 plates may be placed on bottom cover layer 1210, with intervening dielectric layers (not shown). A middle layer 1240 may follow. This may be used as a spacing layer, such as spacing layer 220. Alternating G1&G2 1260 and P1 1250 plates may be placed on middle layer 1240, with intervening dielectric layers (not shown). A top cover layer 1270 may be placed on top of the passive component structure.

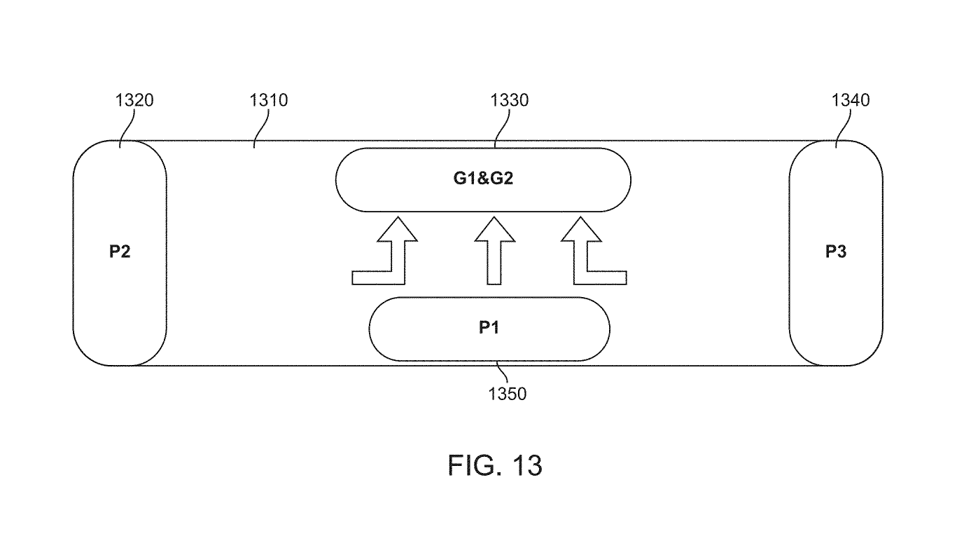

FIG. 13 illustrates a top view of a passive component structure according to an embodiment of the present invention. In this example, three capacitors are included in a single unit. Specifically, a first capacitor has a first node connected to terminal P2 1320, another has a first node connected to terminal P3 1340, while another has a first node connected to terminal P1 1350. Each of these capacitors has a second node connected to terminal G1&G2&G3 1330.

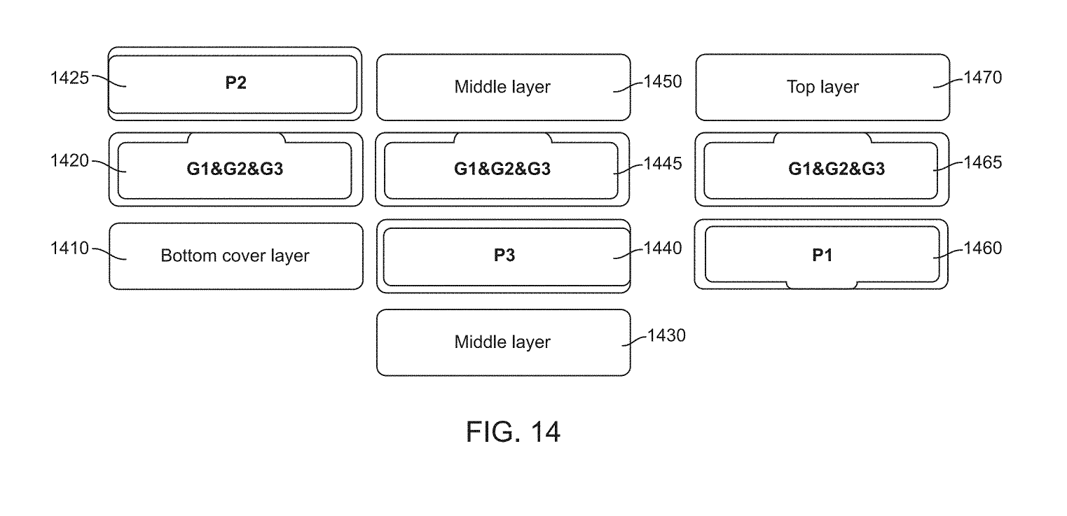

FIG. 14 illustrates the layers of the passive component structure of FIG. 13. A bottom cover layer 1410 may be formed. Alternating G1&G2&G3 1420 and P2 1425 plates may be placed on bottom cover layer 1410, with intervening dielectric layers (not shown). A middle layer 1430 may follow. This may be used as a spacing layer, such as spacing layer 220. Alternating G1&G2&G3 1445 and P3 1440 plates may be placed on middle layer 1430, with intervening dielectric layers (not shown). A second middle layer 1450 may follow. This too may be used as a spacing layer, such as spacing layer 220. Alternating G1&G2&G3 1465 and P1 1460 plates may be placed on middle layer 1450, with intervening dielectric layers (not shown). A top cover layer 1470 may be placed on top of the passive component structure.

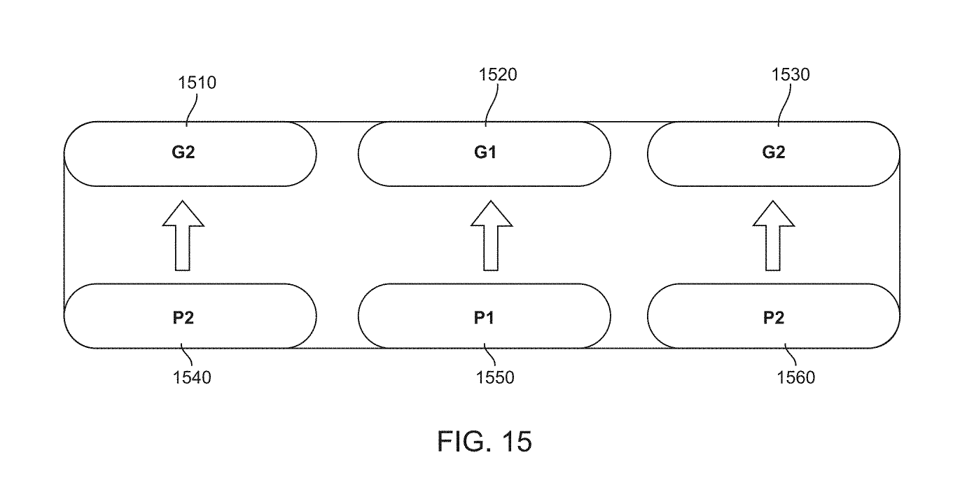

FIG. 15 illustrates a top view of a passive component structure according to an embodiment of the present invention. In this example, first alternating capacitance plates for one capacitor are connected to two terminals, while two capacitors share a single terminal. This may help to reduce the inductance of the capacitor that is connected to the two terminals. Specifically, one capacitor has a first node connected to two terminals P2 1540 and 1560 and a second node connected to terminals G2 1510 and 1520, while another capacitor has a first node connected to terminal P1 1550 and a second node terminal G1 1520.

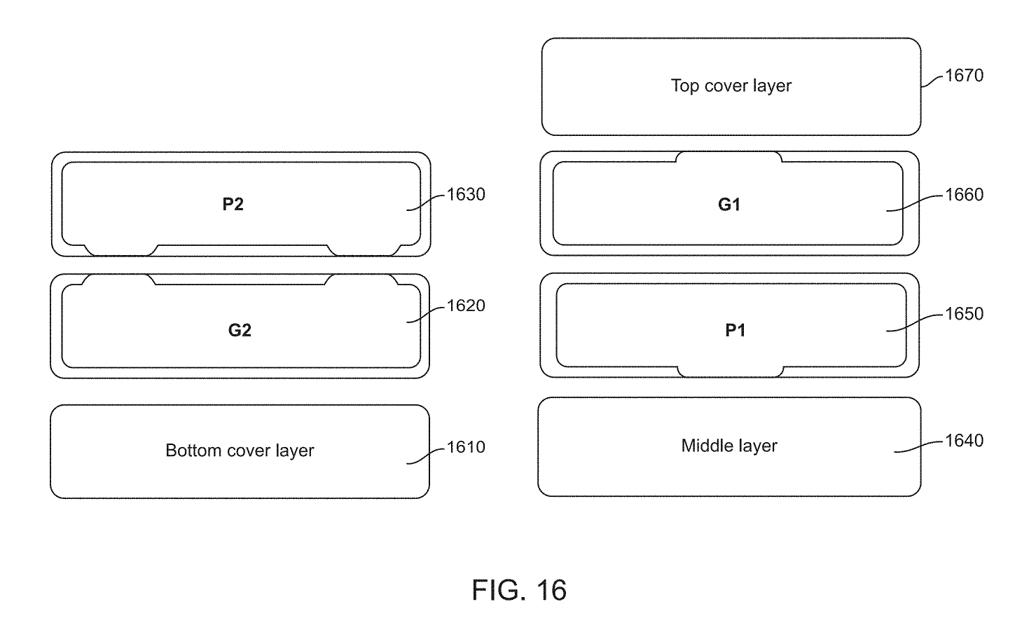

FIG. 16 illustrates the layers of the passive component structure of FIG. 15. A bottom cover layer 1610 may be formed. Alternating G2 1620 and P2 1630 plates may be placed on bottom cover layer 1610, with intervening dielectric layers (not shown). A middle layer 1640 may follow. This may be used as a spacing layer, such as spacing layer 220. Alternating G1 1660 and P1 1650 plates may be placed on middle layer 1640, with intervening dielectric layers (not shown). A top cover layer 1670 may be placed on top of the passive component structure.

In the above embodiments of the present invention, the bottom cover layer, the middle layer or layers, the top cover layers, and the dielectric layers between and at least partially around the capacitor plates may be a dielectric material. The dielectric material may be a ceramic or other material. The ceramics that may be used include class 1 or class 2 ceramics. Examples of such class 1 type of ceramics that may be used as dielectric include C0G, U2J, and others. Examples of such class 2 ceramics that may be used as a dielectric include X5R, X7R, X6S, X7S, and others.

In the above embodiments of the present invention, the capacitor plates may be formed of, or plated or coated with, a conductive material or combination of materials. For example, the capacitor plates may be formed, or plated or coated, using copper, a copper alloy, nickel, a nickel alloy, aluminum, tin, gold, silver, palladium, or other material or combination thereof.

In the above embodiments of the present invention, the terminals or external electrodes may be formed of glass, frit, or other type of ceramic composite. The ceramic composite may include copper, nickel, or one of their alloys, or other material or combination of materials. They may be coated with nickel, tin, copper, or one of their alloys, or other material or combination of materials. An optional intermediate conductive layer formed of one or more of these materials may be included.

In these and other embodiments of the present invention, other types of passive components may be included in a passive component structure. For example, one or more resistors may be included in a passive component structure. These resistors may be made of a ceramic, they may be formed using thin or thick film techniques, they may be formed by etching or printing one or more plates, or they may be formed in other ways of other materials. Inductors may be formed using lengths of external electrodes. Inductors may also be formed by etching or printing spiral or other shapes in one or more plates.

Embodiments of the present invention may provide capacitor structures and other passive component structures that may perform various functions in electronic devices, circuits, and modules, such as SIP modules. For example, the capacitor structures may be used to filter power supplies that are either provided to the electronic circuits, devices, or modules from an external source, or generated on the electronic devices, circuits, or modules by voltage regulators or other circuits. They may be used to filter or AC-couple signals. These passive components may be used to compensate amplifiers and other active circuits. They may be used as integrators or in timing circuits or oscillators, or they may be used for other purposes.

These and other embodiments of the present invention may provide multilayer ceramic capacitors (MLCCs) and other passive component structures that may be packaged in a SIP module or other module or device. When these capacitors have a voltage applied to them, they may expand or contract due to the inverse-piezoelectric or electrostrictive effects. When the applied voltage changes, these effects may modulate one or more surfaces of a SIP module (that is, make one or more surfaces vibrate), essentially causing the SIP module to act as a speaker and produce an audible sound or acoustic noise. Over time, this vibration may also create gaps between the capacitors and any molding or potting compounds used to encapsulate the SIP module. These gaps may become moisture ingress paths that may corrode or damage the capacitor. This moisture may also cause dendrite growth that may lead to the terminals of the capacitors becoming shorted together.

These and other embodiments of the present invention may mitigate these inverse-piezoelectric or electrostrictive effects by coating the capacitors with an elastomer or other pliable or pliant material. Other circuits or components in the SIP module may likewise be coated with an elastomer or other material. The elastomer-coated capacitors and components may then be encapsulated with a molding compound or potting material. The pliable elastomer may absorb vibration or modulation caused by the capacitors, thereby reducing the amount of acoustic noise generated. The elastomer may also act as a moisture barrier, particularly when a hydrophobic elastomer is used.

In these and other embodiments of the present invention, various elastomers may be used. These may be monomers, or a combination of monomers, such as a dipolymer or a terpolymer. Layers of different elastomers may also be used. The elastomers may be belong to an elastomer family such as butadiene rubber, butyl rubber, ethylene propylene rubber, isoprene rubber, natural rubber, silicone rubber, tetrafluoroethylene propylene rubber, polyurethane rubber, nitrile rubber or styrene butadiene rubber, or others. Functionally modified elastomers may also be used in these and other embodiments of the present invention. Additives, such as a solvent, plasticizer and other agents may be added in the elastomer to achieve a desired viscosity, rheology, or other physical properties or characteristic.

In these and other embodiments of the present invention, the elastomers used may have various properties. For example, they may be hydrophobic to reduce possible moisture damage. They may have a glass transition temperature or melting point (if crystalline) of −150 C to −25 C. The elastomer may have a density of 0.8 to 1.4 g/cm³ and a Young's modulus between 0.0001 and 0.1 GPa. The thickness of the elastomer may be between 1 micron and 50 percent of the height of the SIP module, though it may have a greater or lesser thickness.

In these and other embodiments of the present invention, the elastomer, with or without additives, may be applied as a liquid to a surface of a capacitor. The elastomer may be thermally or UV cured, or cured in some other manner. A molding compound may then encapsulate the capacitor and other circuits or components to form the SIP module. Examples are shown in the following figures.

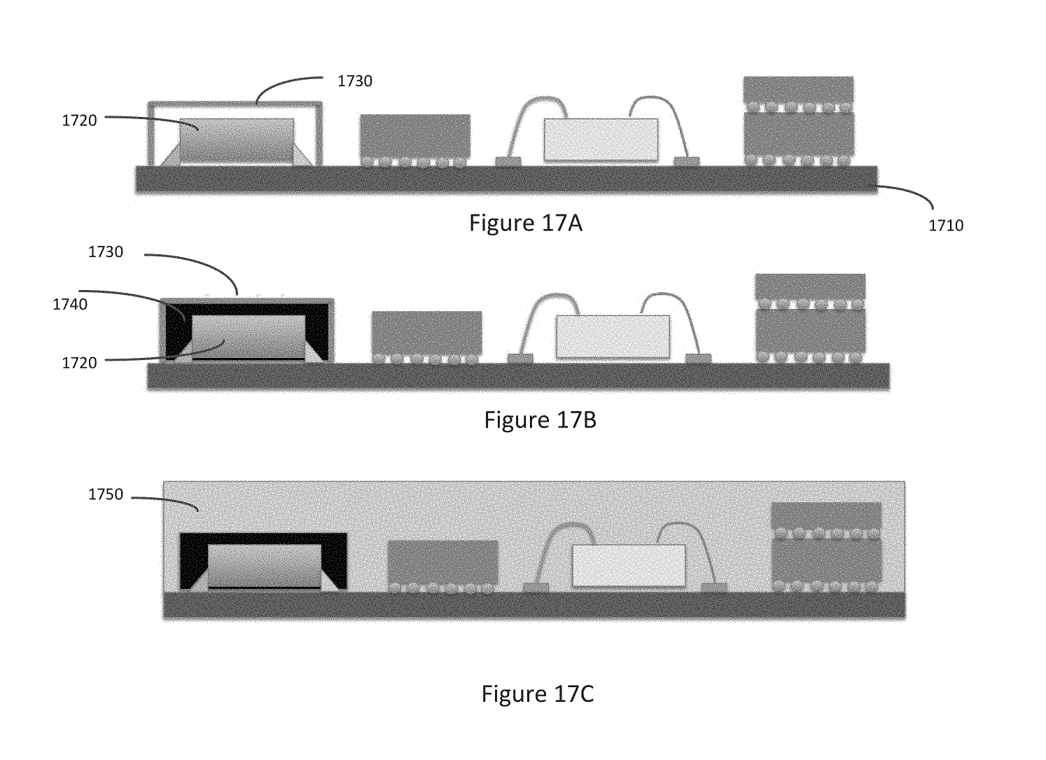

FIGS. 17A-17C illustrate a method of manufacturing a portion of a SIP module according to an embodiment of the present invention. FIG. 17A illustrates a side view of a SIP module formed on a printed circuit board or other appropriate substrate 1710. A number of components including a multilayer ceramic capacitor 1720 may be placed on printed circuit board 1710. A dam 1730 may be formed around multilayer ceramic capacitor 1720. In FIG. 17B, an elastomer 1740 may be deposited or otherwise placed only around multilayer ceramic capacitor 1720 inside of dam 1730. In these and other embodiments of the present invention, elastomer 1740 may be deposited or otherwise placed around multilayer ceramic capacitor 1720 inside of dam 1730 and elsewhere in the SIP module. The elastomer may then be cured, for example by heat, UV, or other method. The dam 1730 may be removed or left in place. In FIG. 17C, the SIP module may be encapsulated with molding compound 1750. In this example, the elastomer may be isoprene or other appropriate elastomer. For example, Kuraray Liquid Rubber, manufactured by Kuraray America Inc. of Houston, Tex., may be used in these and other embodiments of the present invention.

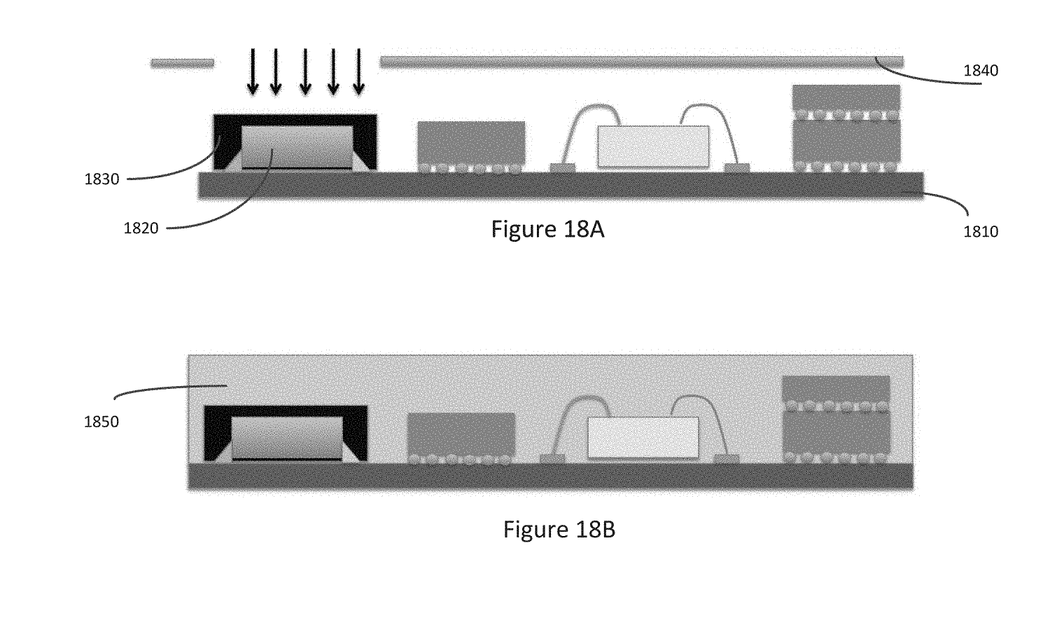

FIGS. 18A-18B illustrate another method of manufacturing a SIP module according to an embodiment of the present invention. In FIG. 18A, a number of components including multilayer ceramic capacitor 1820 may be placed on a printed circuit board or other appropriate substrate 1810. Masking layer 1840 may be the used to define an area of application of an elastomer spray. The elastomeric spray may form elastomeric coating 1830 only around multilayer ceramic capacitor 1820. In these and other embodiments of the present invention, the elastomeric spray may form elastomeric coating 1830 around multilayer ceramic capacitor 1820 and elsewhere in the SIP module. The elastomeric coating 1830 may then be cured, again by heat, UV, or other method. In FIG. 18B, the SIP module may be encapsulated by molding compound 1850. In this example, the elastomer may be butadiene or other type of spray elastomer. For example, Kuraray Liquid Rubber, manufactured by Kuraray America Inc. of Houston, Tex., may be used in these and other embodiments of the present invention. A fast curing elastomer may be used to prevent the sprayed elastomer from dissipating across the SIP module board 1810.

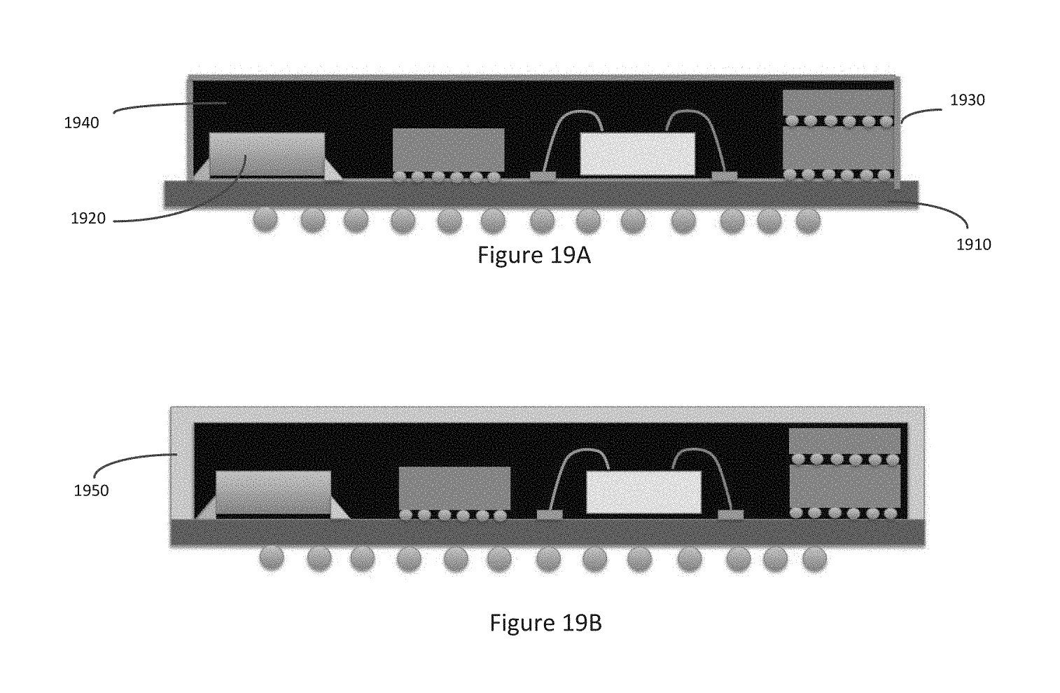

FIGS. 19A-19B illustrate another method of manufacturing a SIP module according to an embodiment of the present invention. In FIG. 19A, a number of components including multilayer ceramic capacitor 1920 may be fixed to a printed circuit board or other appropriate substrate 1910. A dam 1930 may be formed around the multilayer ceramic capacitor 1920 and other components. An elastomer may then be applied and cured. The dam may either be left in place or removed. The SIP module may be encapsulated by the application of molding compound 1950. In this example, the elastomer may be an ethylene propylene diene monomer (EPDM) elastomer, such as one of the materials manufactured by Lion Elastomers LLC of Port Neches, Tex.

In these and other embodiments of the present invention, an elastomer or other elastic substrate may be used to protect a printed circuit board from the compression and expansion of these capacitors due to the inverse-piezoelectric or electrostrictive effects. Specifically, an elastic substrate may be used between a capacitor, such as the multilayer ceramic capacitors and other passive components disclosed above, and a printed circuit board or other substrate. This may protect printed circuit board contacts from stress and may reduce acoustic noise. These substrates may be attached to a board, and then a capacitor may be placed on the substrate. In these and other embodiments of the present invention, the substrate may be attached to a capacitor, and then the substrate and capacitor may be attached to the board. These attachments may be done by welding, regular soldering, laser soldering, hot bar process, or other appropriate technique. The substrates may include an elastic core with conductive pads on its top and bottom, where the conductive pads are connected to each other, either by side plating, through-holes, vias, or other path.

In these and other embodiments of the present invention, the substrate may include one or more elastomers, an elastomeric layer wrapped or coated thermosetting or thermoplastic material, or other materials or combination of materials. The conductive pads may be cladded or glued metal foil, they may be formed by plating, sputtering, vapor deposition, electroless plating, or other appropriate technique. Interconnect between the pads may be formed by through-holes, edge plating or sputtering, or other appropriate technique. The pads may be coated with gold, tin, a tin alloy, or other material.

In these and other embodiments of the present invention, various elastomers may be used for the substrates. These may be monomers, or a combination of monomers, such as a dipolymer or a terpolymer. Layers of different elastomers may also be used. The elastomers may be belong to an elastomer family such as butadiene rubber, butyl rubber, ethylene propylene rubber, isoprene rubber, natural rubber, silicone rubber, tetrafluoroethylene propylene rubber, polyurethane rubber, nitrile rubber or styrene butadiene rubber, or others. Functionally modified elastomers may also be used in these and other embodiments of the present invention. Additives, such as a solvent, plasticizer and other agents may be added in the elastomer to achieve a desired viscosity, rheology, or other physical properties or characteristic.

In these and other embodiments of the present invention, the elastomers used may have various properties. For example, they may be hydrophobic to reduce possible moisture damage. They may have a glass transition temperature or melting point (if crystalline) of −150 C to −25 C. The elastomer may have a density of 0.8 to 1.4 g/cm³ and a Young's modulus between 0.0001 and 0.1 GPa. The shape of the substrate can be square, rectangle, oval, or it may have a different shape. The ratio between the height and the periphery may be less than 30 percent, it may be 30 percent, or it may be greater than 30 percent. The thickness of the substrate may be less than 10 microns, between 10 microns and 3 millimeters, or more than 3 millimeters. Examples are shown in the following figures.

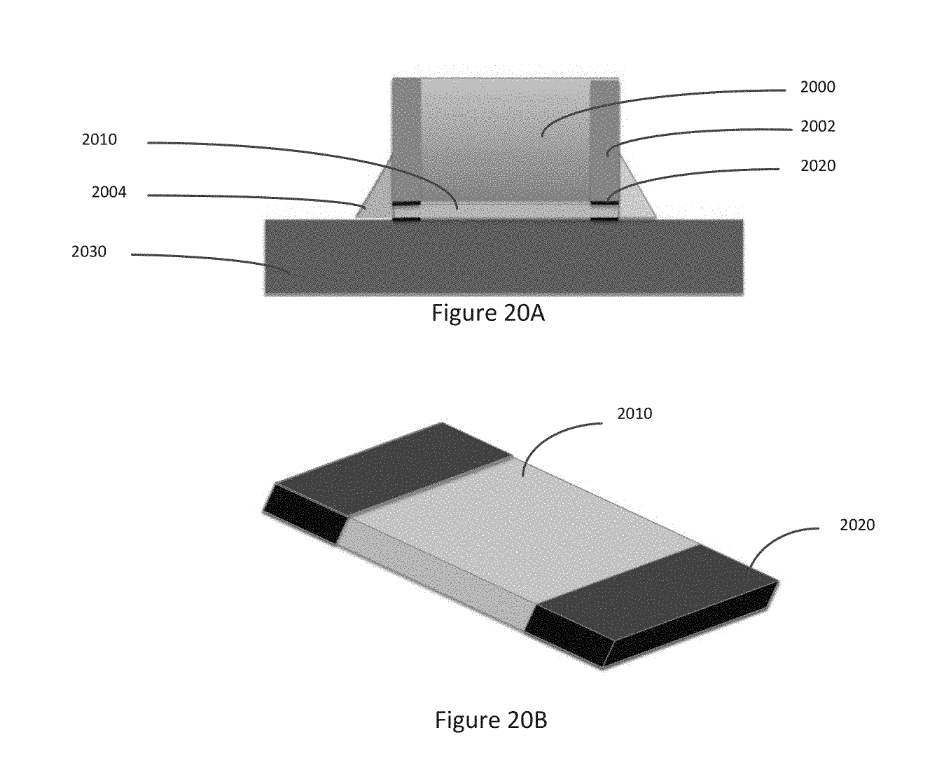

FIGS. 20A-20B illustrate an elastic substrate according to an embodiment of the present invention. In FIG. 20A, multilayer ceramic capacitor 2000 may be attached to an elastic substrate 2010, which may in turn be attached to printed circuit board or other appropriate substrate 2030. An elastic substrate may be designed with a single set of pads or with multiple sets of conductive pads. For example, a four-terminal capacitor may be attached to one elastic substrate with four sets of conductive pads, or it may be attached to four elastic substrates, each with a single set of conductive pads. Multilayer ceramic capacitor 2000 may include terminals or contacts 2002. Contacts 2002 may form electrical connections with contacts 2020 on elastic substrate 2010. Contacts 2020 on elastic substrate 2010 may further connect to contacts (not shown) on printed circuit board or other appropriate substrate 2030. Contacts 2002 of multilayer ceramic capacitor 2000 may be soldered with solder 2004 or conductively glued to the contacts on printed circuit board or other appropriate substrate 2030 and contacts 2020 on elastic substrate 2010. FIG. 20B illustrates an example of an elastic substrate. This elastic substrate may be formed of polyurethane. It may have a length of 1.1 mm, a width of a 0.65 mm, and a height of 0.055 mm. The pads may be formed of copper epoxy coated with gold.

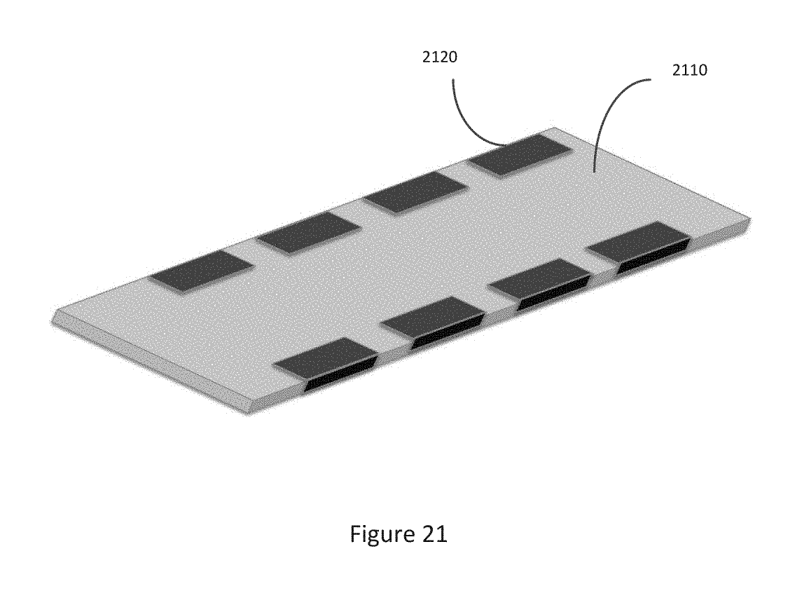

FIG. 21 illustrates another elastic substrate according to an embodiment of the present invention. In this example, elastic substrate 2110 may include contacts or pads 2120. Again, the core material may be polyurethane. This elastic substrate 2110 may have a length of 1 mm, a width of 3 mm, and a height of 0.25 mm. The conductive pads may be copper coated with nickel or tin.

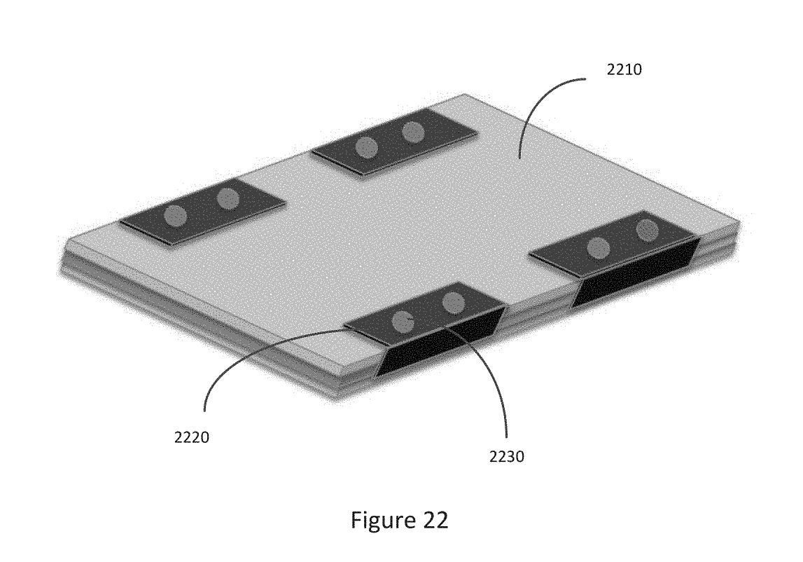

FIG. 22 illustrates another elastic substrate according to an embodiment of the present invention. In this example, elastic substrate 2210 may include pads or contacts 2220. Through-holes or vias 2230 may connect a top of contact 2020 to a bottom of contact 2020 on the top and bottom sides respectively of elastic substrate 2210. In this example, the core material may be formed of isoprene rubber layers on top and bottom with an intermediate or middle layer of FR4 or polyimide. Contacts 2220 may be formed of plated copper with plated copper filled through-holes or vias 2230.

In the above examples, embodiments of the present invention may provide multilayer ceramic capacitors and other passive devices, as well as methods and structures for incorporating these components in a SIP module or other type of device. These and other embodiments of the present invention may further provide enhancements and improvements to other types of components. For example, these and other embodiments of the present invention may provide improvements to electrolytic capacitors. These and other embodiments of the present invention may also provide improved electrolytic capacitors and their method of manufacture.

In the above examples, elastomers may be used to block moisture ingress. This use of elastomers may extend to preventing or limiting moisture ingress in electrolytic capacitors and other devices. In these and other embodiments of the present invention, elastomers may be used as coatings for lead frames inside electrolytic capacitors. These pliable coatings may be initially compressed, and may later expand to fill a gap between the lead frame and the remainder of the capacitor that may result due to environmental stress and changes. The lead frame itself may also be modified to improve the resulting seal. The thickness of these coatings may be between 1 micron and 50 percent of the package height. The coatings may have a length between 1 micron and 50 percent of the package length. The coatings may be applied either as part of the lead frame manufacturing or the capacitor manufacturing.

In these and other embodiments of the present invention, various elastomers may be used. These may be monomers, or a combination of monomers, such as a dipolymer or a terpolymer. Layers of different elastomers may also be used. The elastomers may be belong to an elastomer family such as butadiene rubber, butyl rubber, ethylene propylene rubber, isoprene rubber, natural rubber, silicone rubber, tetrafluoroethylene propylene rubber, polyurethane rubber, nitrile rubber or styrene butadiene rubber, or others. Functionally modified elastomers may also be used in these and other embodiments of the present invention. Additives, such as fillers or foaming agents can be added to adjust elasticity, resilience, tortuosity, pore size distribution density, molecular weight, surface tension and other physical properties.

In these and other embodiments of the present invention, the elastomers used may have various properties. For example, they may be hydrophobic to reduce possible moisture damage. The elastomers may have a glass transition temperature or melting point (if crystalline) of −150 C to −25 C. The elastomer may have a density of 0.8 to 1.4 g/cm3. Where the coating is porous, the density may be between 0.025 to 0.8 g/cm³. Examples are shown in the following figure.

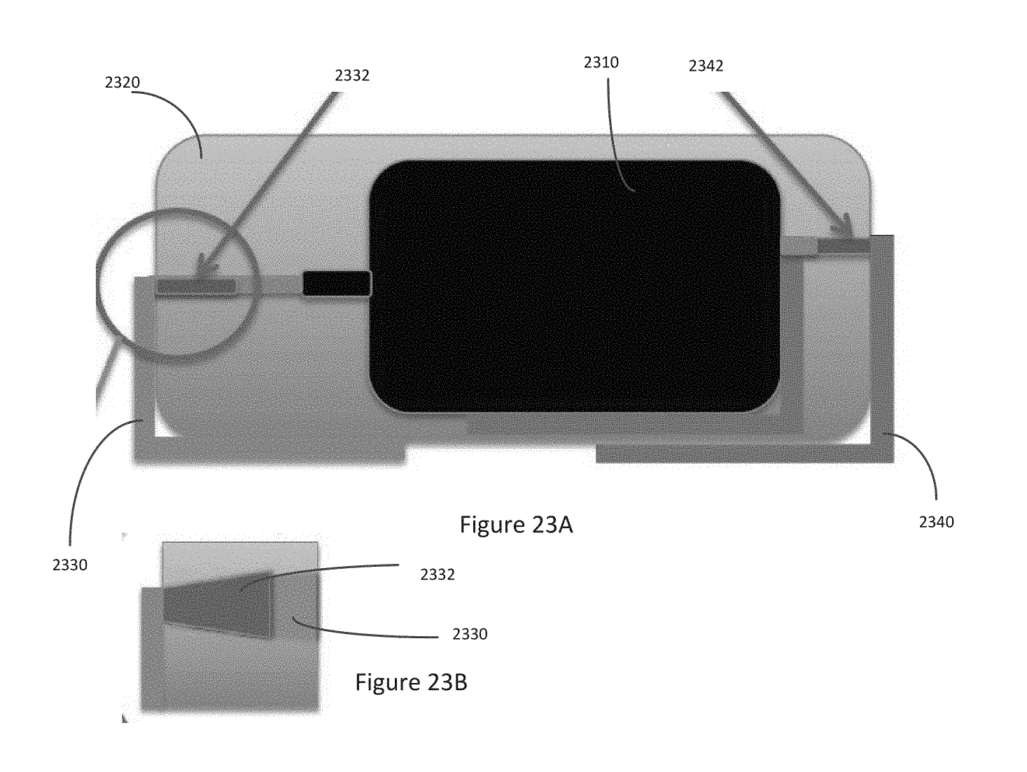

FIGS. 23A-23B illustrate a coating on a lead frame of an electrolytic capacitor according to an embodiment of the present invention. In FIG. 23, a capacitor 2310 may be housed in housing 2320 formed of an epoxy or other material. Lead frames 2330 and 2340 may provide an external connection to internal capacitor 2310. Elastomeric layers or coatings 2332 and 2342 may be formed around lead frames 2330 and 2340 as shown. These elastomeric layers may seal a gap between lead frames 2330 and 2340 and a housing 2320 formed of epoxy or other material. As the capacitor ages and gaps began to open between lead frames 2330 and 2340 and a housing 2320 formed of epoxy or other material, the elastomeric coatings 2332 and 2342 may expand to fill the gap and prevent moisture ingress into the capacitor.

The lead frames themselves may be modified to improve this moisture ingress reduction. That is, the lead frames 2330 and 2340 may be modified to improve the sealing capabilities of the elastomeric coatings 2332 and 2342. In FIG. 23B, lead frame 2330 may be tapered to a narrowing width at an outside edge of epoxy housing 2320. This taper may have a 15 degree slope, or the slope may have another angle. Lead frame 2340 may be similarly tapered.

Unfortunately, these lead frames may consume space inside a capacitor. Also, the bending and trimming of these lead frames may mechanically overstress a capacitor, thus leading to yield loss, thereby wasting resources. Accordingly, these and other embodiments of the present invention may provide capacitors that do not employ a lead frame. Instead, interconnects between internal capacitor elements and external contacts or terminals are provided using applied metal, metal alloy, conductive adhesive, or other material. Examples are shown in the following figures.

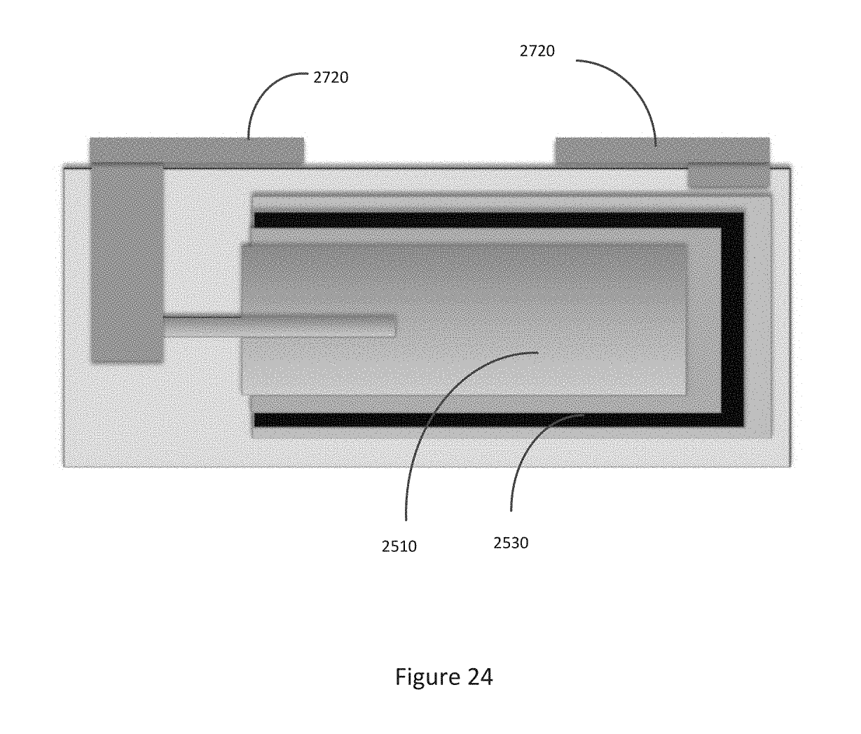

FIG. 24 illustrates a capacitor according to an embodiment of the present invention. This capacitor may include anode 2510, cathode 2530, and contacts 2720. Further details are shown in the following figures.

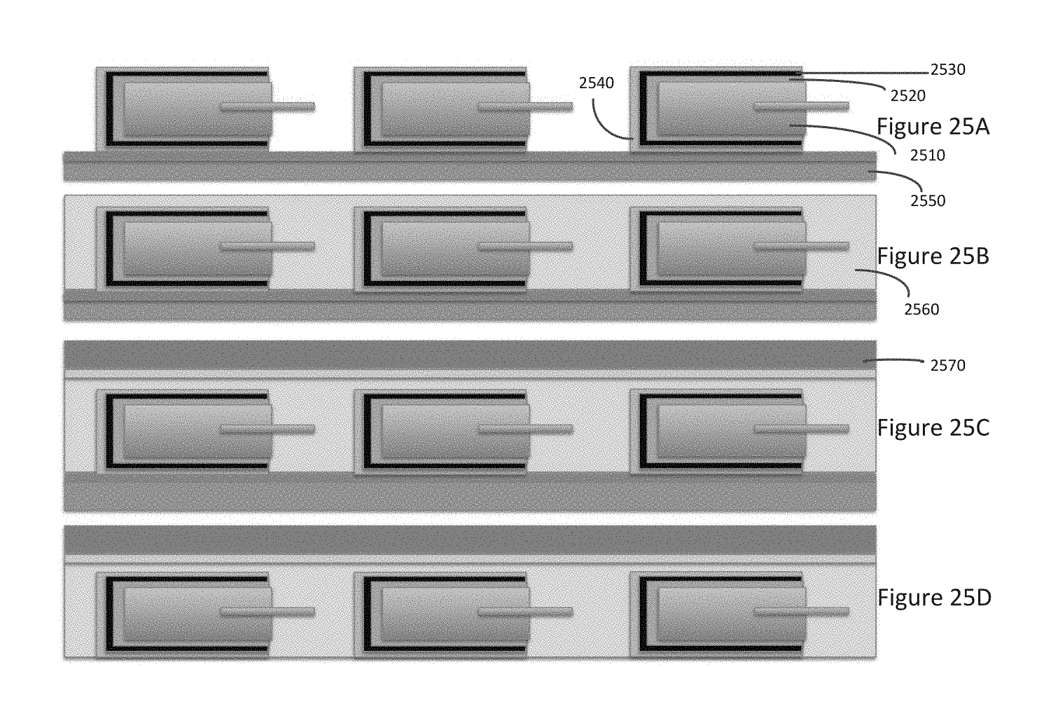

FIGS. 25A-25D, 26A-26C, 27A-27C, and 28A-28B illustrate a method of forming the capacitor of FIG. 24. In FIG. 25A, an anode 2510 is provided. Anode 2510 may be formed using a valve metal such as oxidized tantalum, niobium, niobium monoxide, aluminum, or other material. Anode 2510 may be formed using foil, foam, or a pressed pellet. It may be electrochemically anodized to have the required oxide thickness. A conductive polymer layer 2520 may be formed around anode 2510. A cathode 2530 around the conductive polymer layer 2520 may be formed of a conductive metal oxide such as magnesium oxide, graphite, carbon, ruthenium oxide, or a conductive polymer, such as PEDOT (3,4-ethylenedioxythiophene), PPY (Polypyrrole/Polyurethane), or polyaniline, or other material. An outside of the structure may be coated with conductive a coating such as silver epoxy or other connective material 2540. The structures may be fixed to a first wafer or other appropriate substrate 2550. The structures may be fixed using glue or a first adhesive. In FIG. 25B, an encapsulation layer 2560 may be applied. In FIG. 25C, a second wafer or other appropriate substrate 2570 may be attached with a second, stronger adhesive, while in FIG. 25D, wafer 2550 may be removed.

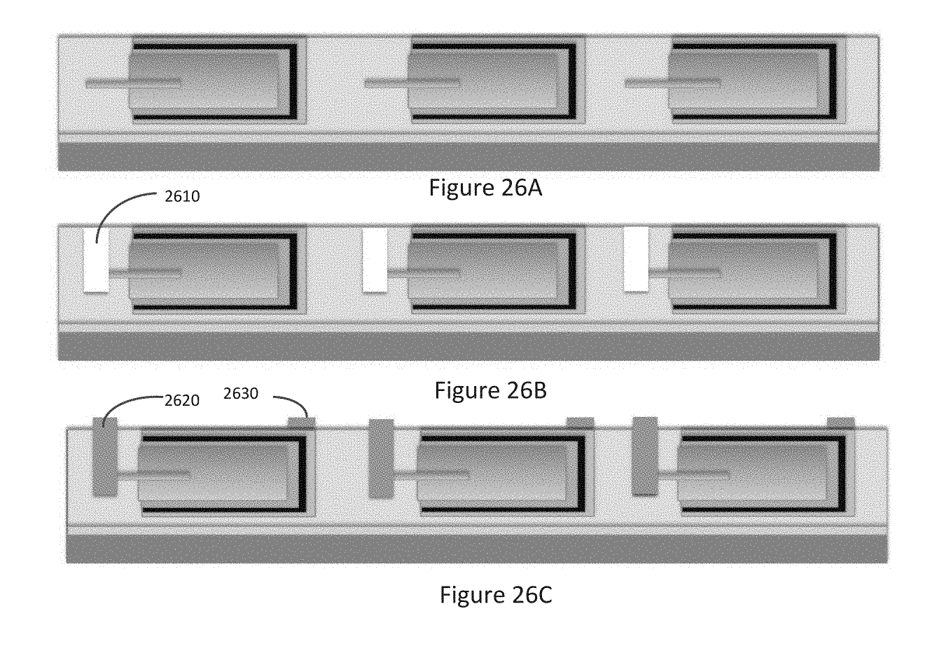

In FIG. 26A, the assembly may be flipped, and sections or streets 2610 may be removed in FIG. 26B, for example by dicing, ablation, water jet cutting, or other technique. Masking may be used to improve alignment during these and other manufacturing steps. In FIG. 26C, conductive material may fill sections 2610 and form portions 2620 and 2630.

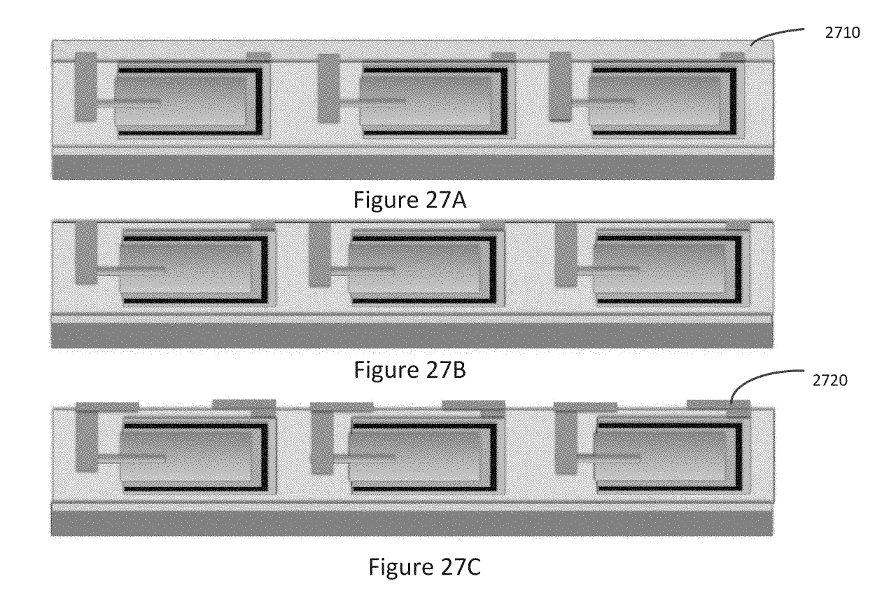

In FIG. 27A, layer 2710 may be formed on a top surface. The encapsulation material 2560 may be cured, again by heat, UV light, or by using another method, and the wafer may be polished in FIG. 27B. Contacts 2720 may be formed in FIG. 27C. Again, masking may be used to improve alignment.

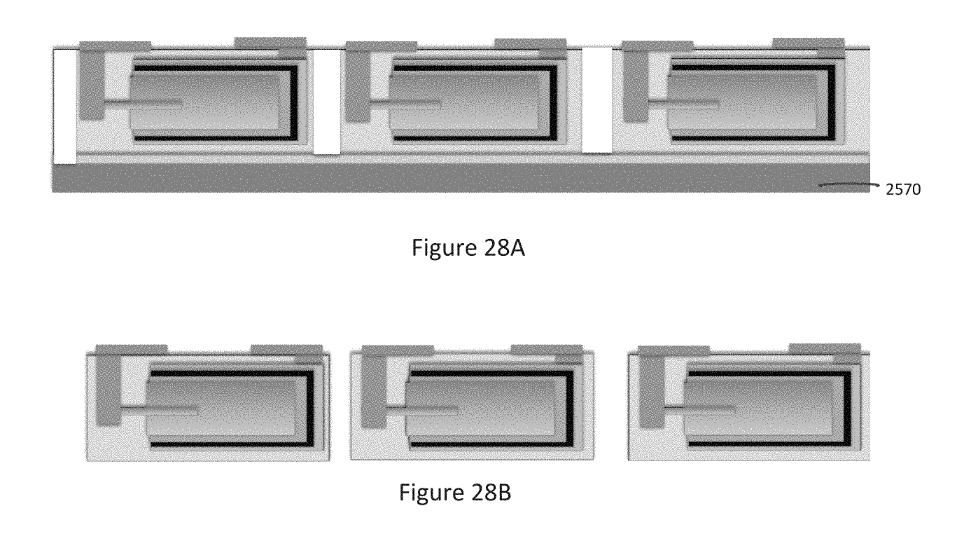

In FIG. 28A, the capacitors may be singulated. Second wafer or other appropriate substrate 2570 may be removed in FIG. 28B. Contacts 2720 may be coated.

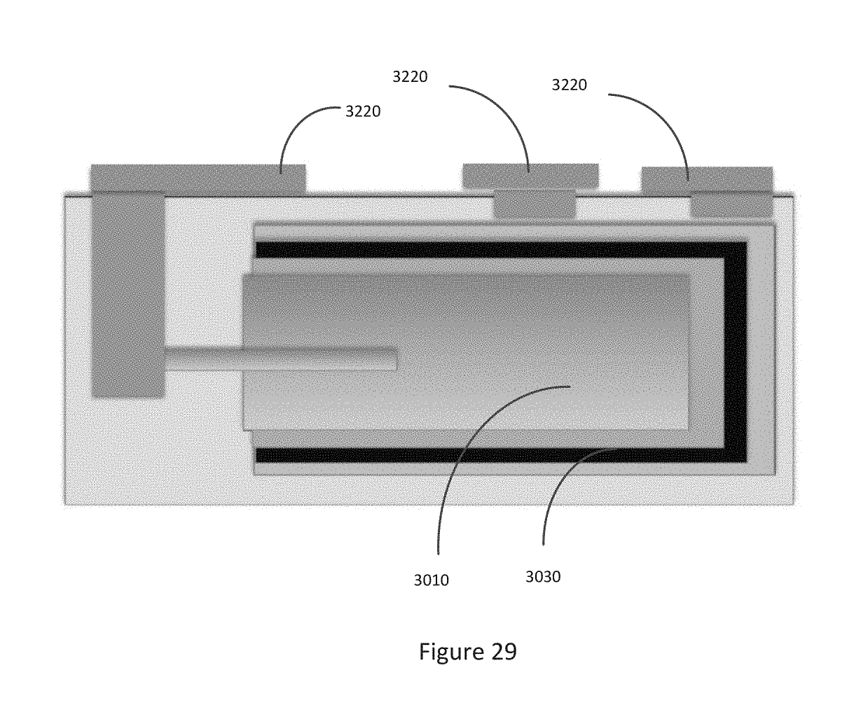

FIG. 29 illustrates a capacitor according to an embodiment of the present invention. This capacitor may include anode 3010, cathode 3030, and contacts 3220. Further details are shown in the following figures.

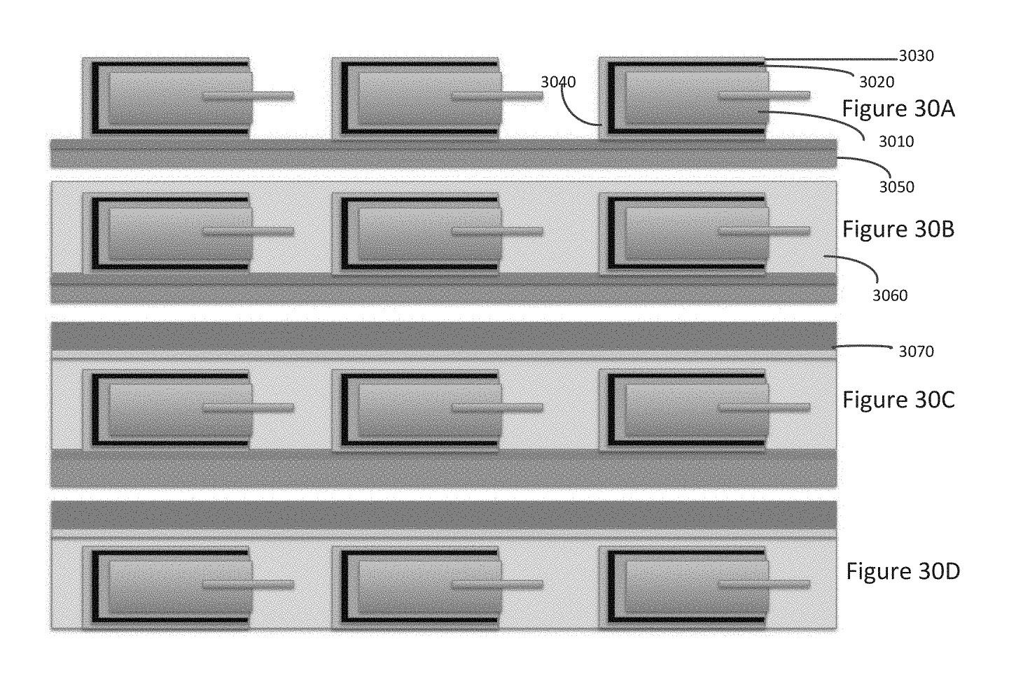

FIGS. 30A-30D, 31A-31C, 32A-32C, and 33A-33B illustrate a method of forming the capacitor of FIG. 29. In FIG. 30A, an anode 3010 is provided. Anode 3010 may be a valve metal such as oxidized tantalum, niobium, niobium monoxide, aluminum, or other material. A conductive polymer layer 3020 may be formed around anode 3010. A cathode layer 3030 around the conductive polymer layer 3020 may be formed of a conductive metal oxide such as magnesium oxide, graphite, carbon, ruthenium oxide, or a conductive polymer, such as PEDOT (3,4-ethylenedioxythiophene), PPY (Polypyrrole/Polyurethane), or polyaniline, or other material. An outside of the structure may be plated with a silver or other connective material 3040. The structures may be fixed to a first wafer or other appropriate substrate 3050. The structures may be fixed using glue or a first adhesive. In FIG. 30B, an encapsulation layer 3060 may be applied. In FIG. 30C, a second wafer or other appropriate substrate 3070 may be attached with a second, stronger adhesive, while in FIG. 30D, wafer 3050 may be removed.

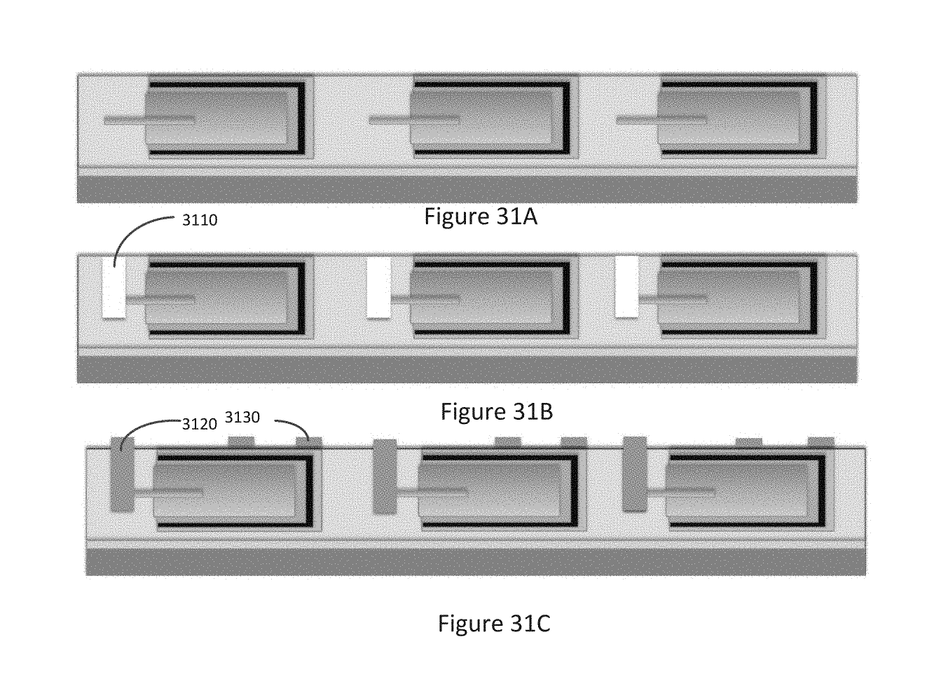

In FIG. 31A, the assembly may be flipped, and sections or streets 3110 may be removed in FIG. 31B, for example by dicing, ablation, water jet cutting, or other technique. Masking may be used to improve alignment during this and other manufacturing steps. In FIG. 31C, conductive material may fill sections 3120 and 3130.

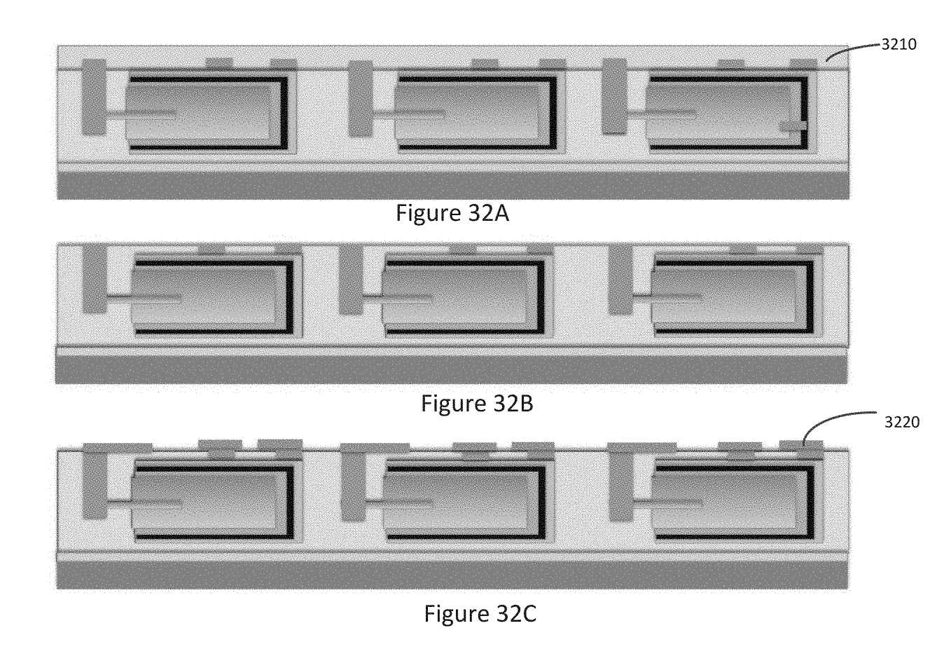

In FIG. 32A, a layer 3210 may be formed on a top surface. The encapsulation layer 3060 may be cured, again by heat, UV light, or by using another method, and the wafer may be polished in FIG. 32B. Contacts 3220 may be formed in FIG. 32C.

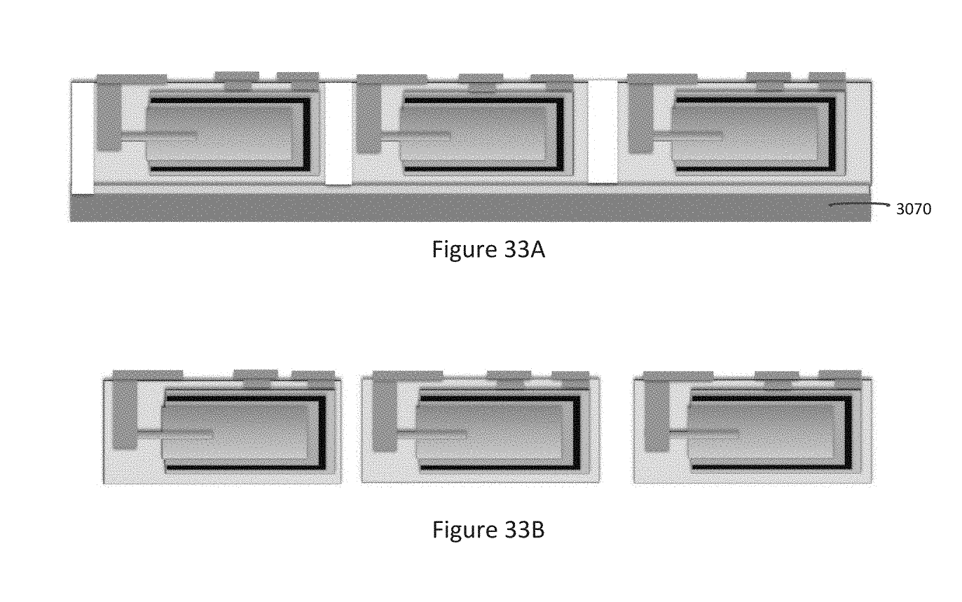

In FIG. 33A, the capacitors may be singulated. Second wafer or other appropriate substrate 3070 may be removed in FIG. 33B. Contacts 3220 may be coated.

Embodiments of the present invention may provide capacitor structures and other passive components that may be used in various types of devices, such as portable computing devices, tablet computers, desktop computers, laptops, all-in-one computers, wearable computing devices, cell phones, smart phones, media phones, storage devices, cases, covers, keyboards, pens, styluses, portable media players, navigation systems, monitors, power supplies, adapters, remote control devices, chargers, and other devices.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

1. A capacitor structure comprising:
a plurality of capacitive plates comprising:
a first set of adjacent plates comprising of a plurality of plates of a first type connected to a first terminal and a plurality of plates of a second type connected to a second terminal, the plates of the first type and the plates of the second type arranged in parallel; and
a second set of adjacent plates comprising of a plurality of plates of the first type connected to the first terminal and a plurality of plates of at third type connected to a third terminal, the a plurality of plates of the first type and the a plurality of plates of the second type arranged in parallel.

2. The capacitor structure of claim 1 wherein the first set of adjacent plates and the second set of adjacent plates are separated by a first spacing layer.

3. The capacitor structure of claim 2 wherein the first spacing layer is formed using a dielectric.

4. The capacitor structure of claim 3 wherein the dielectric is a class 1 or class 2 dielectric.

5. The capacitor structure of claim 3 wherein the dielectric is one of C0G, U2J, X5R, X7R, X6S, and X7S.

6. The capacitor structure of claim 2 wherein the first set of adjacent plates and the second set of adjacent plates are formed using copper.

7. The capacitor structure of claim 2 wherein the first set of adjacent plates and the second set of adjacent plates are formed using nickel.

8. The capacitor structure of claim 2 wherein the first set of adjacent plates and the second set of adjacent plates are formed using at least one of copper, nickel, copper alloy, silver, palladium, or nickel alloy.

9. A capacitor structure comprising:
a first terminal;
a second terminal;
a third terminal;
a first set of adjacent plates comprising:
a first plurality of plates connected to the first terminal; and
a second plurality of plates connected to the second terminal; and
a second set of plates comprising:
a third plurality of plates connected to the first terminal; and
a fourth plurality of plates connected to the third terminal.

10. The capacitor structure of claim 9 wherein the second set of plates are adjacent and the first set of adjacent plates and the second set of adjacent plates are separated by a first spacing layer.

11. The capacitor structure of claim 10 wherein the first spacing layer is formed using a dielectric.

12. The capacitor structure of claim 11 wherein the dielectric is a class 1 or class 2 dielectric.

13. The capacitor structure of claim 11 wherein the dielectric is one of C0G, U2J, X5R, X7R, X6S, and X7S.

14. The capacitor structure of claim 10 wherein the first set of adjacent plates and the second set of adjacent plates are formed using at least one of copper, nickel, copper alloy, silver, palladium, or nickel alloy.

15. An electronic device comprising:
a capacitor structure comprising:
a first capacitor coupled to a first terminal and a second terminal and comprising a first plurality of plates grouped together; and
a second capacitor coupled to a third terminal and a fourth terminal and comprising a second plurality of plates grouped together,
wherein all of the first plurality of plates for the first capacitor are above the second capacitor, and
wherein all of the second plurality of plates for the second capacitor are below the first capacitor.

16. The electronic device of claim 15 wherein the first terminal and the third terminal are connected together.

17. The electronic device of claim 15 wherein the first plurality of plates and the second plurality of plates are separated by a dielectric, wherein the dielectric is one of X5R, X7R, X6S, and X7S.

18. The electronic device of claim 15 further comprising:
a printed circuit board; and
an elastomeric substrate between the capacitor structure and the printed circuit board, such that contacts on the capacitor structure are electrically connected to contacts on the elastomeric substrate and the contacts on the elastomeric substrate are further electrically connected to contacts on the printed circuit board.

19. The electronic device of claim 18 wherein the elastomeric substrate is formed of a layer of FR4 between two layers of isoprene rubber.

20. The electronic device of claim 15 wherein the capacitor structure is at least partially coated with an elastomer and encapsulated in a molding compound.

21. (canceled)

22. (canceled)
